(19) United States
(12) Patent Application Publication
(10) Pub. No.: US 2013/0140442 A1
(43) Pub. Date: Jun. 6, 2013

(54) AMPLIFYING CIRCUIT AND MANUFACTURING METHOD, SOLID-STATE IMAGING ELEMENT, AND ELECTRONIC DEVICE

(71) Applicant: Sony Corporation, Tokyo (JP)

(72) Inventors: Takeshi Yanagita, Tokyo (JP); Keiji Mabuchi, Kanagawa (JP); Toru Shirakata, Kanagawa (JP); Takashi Abe, Kanagawa (JP); Takafumi Morikawa, Kanagawa (JP)

(73) Assignee: SONY CORPORATION, Tokyo (JP)

(21) Appl. No.: 13/671,167

(22) Filed: Nov. 7, 2012

(30) Foreign Application Priority Data
Dec. 2, 2011 (JP) 2011-264851
Dec. 14, 2011 (JP) 2011-273818

(51) Int. Cl. H01L 31/08; H05K 13/00; H03F 3/16

(52) U.S. Cl. CPC H01L 31/08; H03F 3/16; H05K 13/00
USPC 250/214 A; 250/206; 330/277; 29/842

(57) ABSTRACT

Disclosed herein is a solid-state imaging element including: a photoelectric conversion section configured to generate a charge according to received light; and a plurality of active elements configured to perform predetermined operation on the charge generated in the photoelectric conversion section, wherein a part of a gate electrode possessed by one of the active elements has a projection part buried in a substrate in which the photoelectric conversion section is formed. Thus, it is possible to suppress the occurrence of noise, and provide excellent image quality with a smaller area.

### BACKGROUND

The present disclosure relates to a solid-state imaging element and an electronic device, and particularly to a solid-state imaging element and an electronic device that can suppress the occurrence of noise and provide better image quality.

In related art, solid-state imaging elements such as CMOS (Complementary Metal Oxide Semiconductor) image sensors, CCDs (Charge Coupled Devices), and the like have been widely used in digital still cameras, digital video cameras, and the like. A solid-state imaging element has a light receiving surface in which a plurality of pixels having a PD (photodiode) as a photoelectric conversion section, a plurality of transistors, and the like are arranged two-dimensionally. Each of the pixels subjects incident light to photoelectric conversion.

In a CMOS image sensor, for example, a charge accumulated by photoelectric conversion in a PD is transferred to an FD (Floating Diffusion) as a floating diffusion region via a transfer transistor. Then, an amplifying transistor converts the charge accumulated in the FD into a pixel signal according to the level of the charge. The pixel signal is output via a selecting transistor.

The structure of an amplifying transistor in related art will be described with reference to FIGS. 1A to 1C.

FIG. 1A shows an example of a planar constitution of the amplifying transistor 1. FIG. 1B shows an example of a constitution in section in a direction of width of the amplifying transistor 1 (section taken along a line A-A′ of FIG. 1A). FIG. 1C shows an example of a constitution in section in a direction of length of the amplifying transistor 1 (section taken along a line B-B′ of FIG. 1A).

As shown in FIGS. 1A to 1C, the amplifying transistor 1 has a source region 3 and a drain region 4 formed in a silicon substrate 2, a channel region 5 formed between the source region 3 and the drain region 4, and a gate electrode 6 formed so as to cover the channel region 5. In addition, element isolation regions 7 for isolating the amplifying transistor 1 from other elements such as a PD and the like are formed at both ends of the gate electrode 6 in the direction of width of the amplifying transistor 1 (direction of the line A-A′ of FIG. 1A) so as to sandwich the amplifying transistor 1.

Generally, noise occurring in the amplifying transistor 1 is directly added to a pixel signal, and output. Thus, at a time of imaging at low illuminance, for example, an S/N (signal to noise ratio) is lowered, and image quality is degraded. In particular, 1/f noise and burst noise occurring in the amplifying transistor 1 have great effects. For higher image quality of a solid-state imaging element, the occurrence of 1/f noise and burst noise needs to be suppressed.

In addition, as disclosed in Japanese Patent Laid-Open No. 2006-253316, 1/f noise is known to be dependent on gate length and gate width. Increasing the size of the amplifying transistor is effective in reducing 1/f noise.

A pixel in related art will next be described with reference to FIGS. 2A and 2B. FIG. 2A is a circuit diagram of the pixel. FIG. 2B shows an example of a sectional constitution.

As shown in FIG. 2A, the pixel 1021 includes a PD (photodiode) 1022, a transfer transistor 1023, an FD (Floating Diffusion) 1024, an amplifying transistor 1025, a selecting transistor 1026, and a reset transistor 1027. In addition, the pixel 1021 is connected with a vertical signal line 1028 for outputting a pixel signal from the pixel 1021, and is connected with horizontal signal lines 1029TRF, 1029SEL, and 1029RST for supplying signals for driving the pixel 1021.

In addition, as shown in FIG. 2B, in the pixel 1021, an N-type PD 1022, a P-type region 1032a for isolating the photodiode, and a P-well 1032b for the transistors are formed in an N-type silicon substrate 1031, and N-type regions 1033-1 to 1033-4 are formed in the P-well 1032b. In addition, gate electrodes 1034-1 to 1034-4 are formed on the surface of the silicon substrate 1031 with a gate insulating film not shown in the figures interposed between the gate electrodes 1034-1 to 1034-4 and the surface of the silicon substrate 1031.

The gate electrode 1034-1 forming the transfer transistor 1023 is disposed at a position between the PD 1022 and the N-type region 1033-1 forming the FD 1024. The gate electrode 1034-2 forming the reset transistor 1027 is disposed at a position between the N-type regions 1033-1 and 1033-2. In addition, the N-type region 1033-2 is connected with a power supply potential VDD.

The gate electrode 1034-3 forming the amplifying transistor 1025 is disposed at a position between the N-type regions 1033-2 and 1033-3. The gate electrode 1034-4 forming the selecting transistor 1026 is disposed at a position between the N-type regions 1033-3 and 1033-4. In addition, the N-type region 1033-4 is connected with the vertical signal line 1028.

Thus, in the pixel 1021 in related art, the transfer transistor 1023, the amplifying transistor 1025, the selecting transistor 1026, and the reset transistor 1027 are formed within the same P-well 1032b.

An imaging element having the pixel 1021 of such a constitution increases a loss of gain in the amplifying transistor 1025 (amplifying circuit 1011) due to a substrate bias effect.

Accordingly, Japanese Patent Laid-Open No. 2003-273132 (hereinafter referred to as Patent Document 2) and Japanese Patent Laid-Open No. 2011-119441 (hereinafter referred to as Patent Document 3), for example, disclose imaging elements in which an amplifying transistor (amplifier transistor) of a source follower circuit has an N-well obtained by forming a well into different wells, coupling between the source and the well of the amplifying transistor is thereby made possible, and a gain is improved.

### SUMMARY

However, as the number of pixels of solid-state imaging elements is increased, the pixels are becoming smaller. It is therefore difficult to reduce the size of other elements such as PDs and the like in order to increase the size of the transistor. Thus, the area of a region that can be used for the transistor is limited. The occurrence of 1/f noise and burst noise is desired to be suppressed by a method other than a method of increasing the size of the transistor.

Further, as disclosed in Patent Documents 2 and 3, in the amplifying transistor in the constitution where the different wells are formed, a source voltage is applied to the well, so that a large area is required to maintain a well withstand voltage. In addition, the threshold value of the amplifying transistor is determined by the concentration of the well. It is therefore difficult to obtain linearity of an output signal as an imaging characteristic of the imaging element. In addition, because the threshold value of the source follower varies according to a signal level due to a substrate bias effect, nonlinearity may occur in output of the pixels.

The present disclosure has been made in view of such a situation. It is desirable to be able to suppress the occurrence of noise, and provide excellent image quality with a smaller area.

According to one embodiment of the present disclosure, there is provided a solid-state imaging element including: a photoelectric conversion section configured to generate a charge according to received light; and a plurality of active elements configured to perform predetermined operation on the charge generated in the photoelectric conversion section, wherein a part of a gate electrode possessed by one of the active elements has a projection part buried in a substrate in which the photoelectric conversion section is formed.

According to one embodiment of the present disclosure, there is provided an electronic device including a solid-state imaging element, the solid-state imaging element including a photoelectric conversion section configured to generate a charge according to received light; and a plurality of active elements configured to perform predetermined operation on the charge generated in the photoelectric conversion section, wherein a part of a gate electrode possessed by one of the active elements has a projection part buried in a substrate in which the photoelectric conversion section is formed.

In one embodiment of the present disclosure, a part of a gate electrode possessed by active elements has a projection part buried in a substrate in which a photoelectric conversion section is formed.

According to one embodiment of the present disclosure, there is provided an amplifying circuit including: an impurity region of a first type formed in a surface silicon layer of a semiconductor substrate, the semiconductor substrate having an insulating film formed between a silicon substrate layer of the semiconductor substrate and the surface silicon layer, the impurity region of the first type being formed from a surface of the surface silicon layer to the insulating film; a gate electrode formed on a surface side of the semiconductor substrate; an electrically independent impurity region of a second type surrounded by the impurity region of the first type in two positions and the insulating film; and a connecting section configured to connect the impurity region of the second type to one of the impurity region of the first type and the gate electrode.

According to one embodiment of the present disclosure, there is provided a manufacturing method including: forming an impurity region of a first type in a surface silicon layer of a semiconductor substrate, the semiconductor substrate having an insulating film formed between a silicon substrate layer of the semiconductor substrate and the surface silicon layer, from a surface of the surface silicon layer to the insulating film; forming a gate electrode on a surface side of the semiconductor substrate; and connecting an electrically independent impurity region of a second type surrounded by the impurity region of the first type in two positions and the insulating film to one of the impurity region of the first type and the gate electrode.

According to one embodiment of the present disclosure, there is provided an imaging element including: a photoelectric conversion section configured to generate a charge according to a light amount of received light; and an amplifying section configured to amplify the charge generated in the photoelectric conversion section, and output the amplified charge, wherein the amplifying section includes an impurity region of a first type formed in a surface silicon layer of a semiconductor substrate, the semiconductor substrate having an insulating film formed between a silicon substrate layer of the semiconductor substrate and the surface silicon layer, the impurity region of the first type being formed from a surface of the surface silicon layer to the insulating film, a gate electrode formed on a surface side of the semiconductor substrate, an electrically independent impurity region of a second type surrounded by the impurity region of the first type in two positions and the insulating film, and a connecting section configured to connect the impurity region of the second type to one of the impurity region of the first type and the gate electrode.

According to one embodiment of the present disclosure, there is provided an electronic device including an imaging element, the imaging element including: a photoelectric conversion section configured to generate a charge according to a light amount of received light; and an amplifying section configured to amplify the charge generated in the photoelectric conversion section, and output the amplified charge, wherein the amplifying section includes an impurity region of a first type formed in a surface silicon layer of a semiconductor substrate, the semiconductor substrate having an insulating film formed between a silicon substrate layer of the semiconductor substrate and the surface silicon layer, the impurity region of the first type being formed from a surface of the surface silicon layer to the insulating film, a gate electrode formed on a surface side of the semiconductor substrate, an electrically independent impurity region of a second type surrounded by the impurity region of the first type in two positions and the insulating film, and a connecting section configured to connect the impurity region of the second type to one of the impurity region of the first type and the gate electrode.

In one embodiment of the present disclosure, an impurity region of a first type is formed in a surface silicon layer of a semiconductor substrate, the semiconductor substrate having an insulating film formed between a silicon substrate layer of the semiconductor substrate and the surface silicon layer, from a surface of the surface silicon layer to the insulating film, and a gate electrode is formed on the surface side of the semiconductor substrate. An electrically independent impurity region of a second type surrounded by the impurity region of the first type in two positions and the insulating film is connected to one of the impurity region of the first type and the gate electrode.

According to one embodiment of the present disclosure, it is possible to suppress the occurrence of noise, and obtain better image quality.

### BRIEF DESCRIPTION OF THE DRAWINGS

FIGS. 1A, 1B, and 1C are diagrams of assistance in explaining an amplifying transistor in related art;

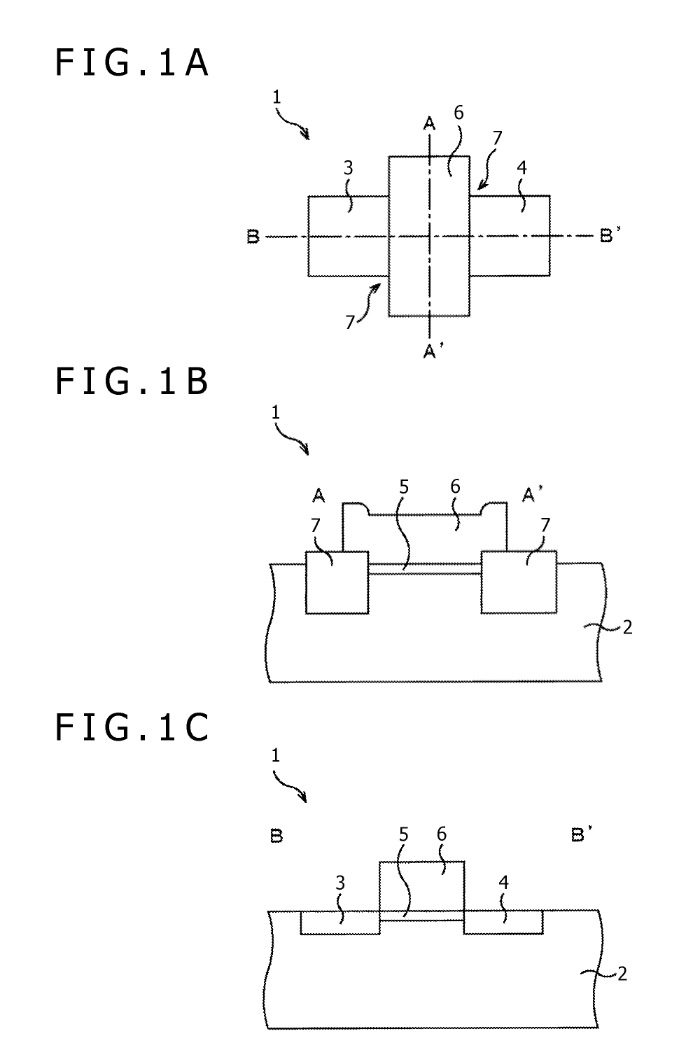

FIGS. 2A and 2B are diagrams showing an example of constitution of a pixel in related art;

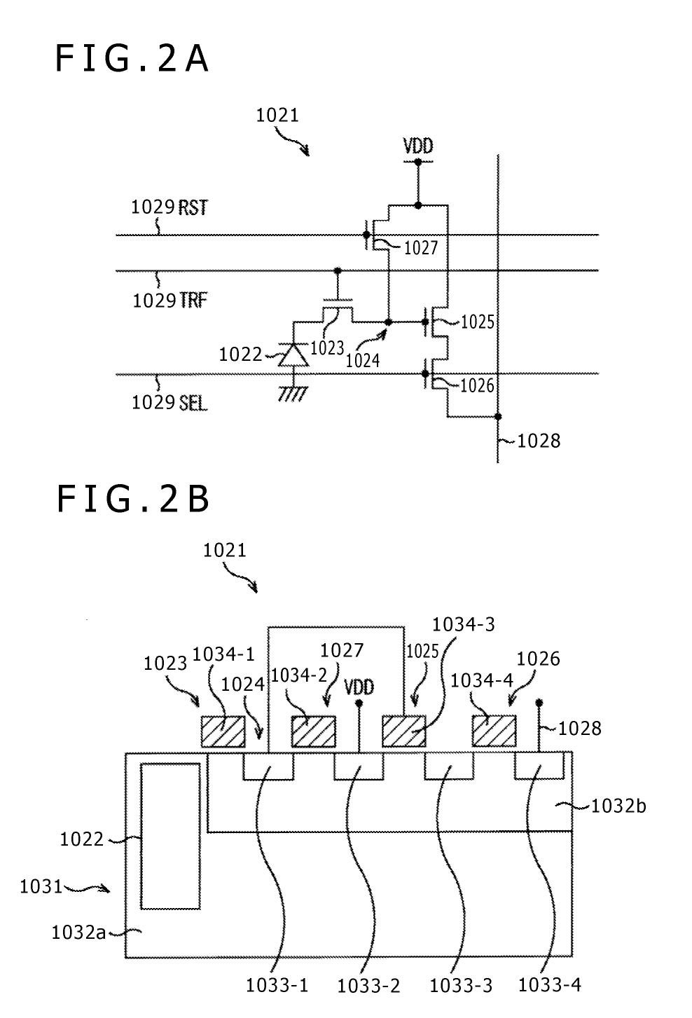

FIG. 3 is a block diagram showing an example of configuration of an embodiment of a solid-state imaging element to which the present technology is applied;

FIG. 4 is a circuit diagram showing an example of configuration of pixels of a pixel array section and a peripheral circuit;

FIG. 5 is a diagram showing an example of timing of driving pixels;

FIGS. 6A and 6B are diagrams showing a first example of configuration of an amplifying transistor;

FIGS. 7A and 7B are diagrams showing a second example of configuration of an amplifying transistor;

FIGS. 8A and 8B are diagrams showing a third example of configuration of an amplifying transistor;

FIGS. 9A and 9B are diagrams showing a fourth example of configuration of an amplifying transistor;

FIGS. 10A and 10B are diagrams showing a fifth example of configuration of an amplifying transistor;

FIGS. 11A, 11B, and 11C are diagrams showing an example of configuration of a pixel;

FIGS. 12A, 12B, and 12C are diagrams showing an example of configuration of a first embodiment of an amplifying circuit to which the present technology is applied;

FIG. 13 is a diagram showing an example of modification of the amplifying circuit according to the first embodiment;

FIGS. 14A, 14B, and 14C are diagrams showing an example of configuration using a constant-current source;

FIGS. 15A and 15B are diagrams showing a first example of configuration of a pixel;

FIGS. 16A, 16B, and 16C are diagrams showing an example of configuration of a second embodiment of an amplifying circuit to which the present technology is applied;

FIGS. 17A, 17B, and 17C are diagrams showing an example of configuration using a constant-current source;

FIGS. 18A and 18B are diagrams showing a second example of configuration of a pixel;

FIGS. 19A and 19B are diagrams showing a third example of configuration of a pixel;

FIGS. 20A and 20B are diagrams showing a fourth example of configuration of a pixel;

FIG. 21 is a diagram showing a fifth example of configuration of a pixel;

FIG. 22 is a diagram showing a sixth example of configuration of a pixel;

FIG. 23 is a diagram showing a seventh example of configuration of a pixel;

FIG. 24 is a diagram showing an eighth example of configuration of a pixel;

FIGS. 25A and 25B are diagrams showing an example of configuration of a solid-state imaging element; and

FIG. 26 is a block diagram showing an example of configuration of an imaging device included in an electronic device.

### DETAILED DESCRIPTION OF THE PREFERRED EMBODIMENTS

Concrete embodiments to which the present technology is applied will hereinafter be described in detail with reference to the drawings.

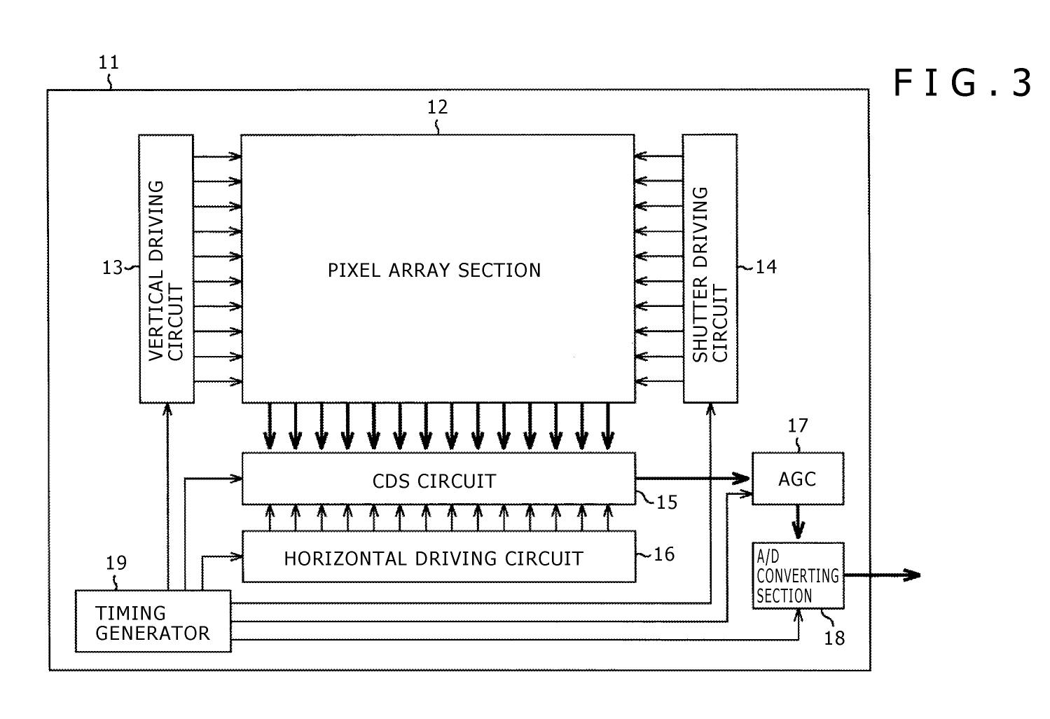

FIG. 3 is a block diagram showing an example of configuration of one embodiment of a solid-state imaging element to which the present technology is applied.

In FIG. 3, the solid-state imaging element 11 is a CMOS type solid-state imaging element. The solid-state imaging element 11 includes a pixel array section 12, a vertical driving circuit 13, a shutter driving circuit 14, a CDS (Correlated Double Sampling) circuit 15, a horizontal driving circuit 16, an AGC (Automatic Gain Controller) 17, an A/D (Analog/Digital) converting section 18, and a timing generator 19.

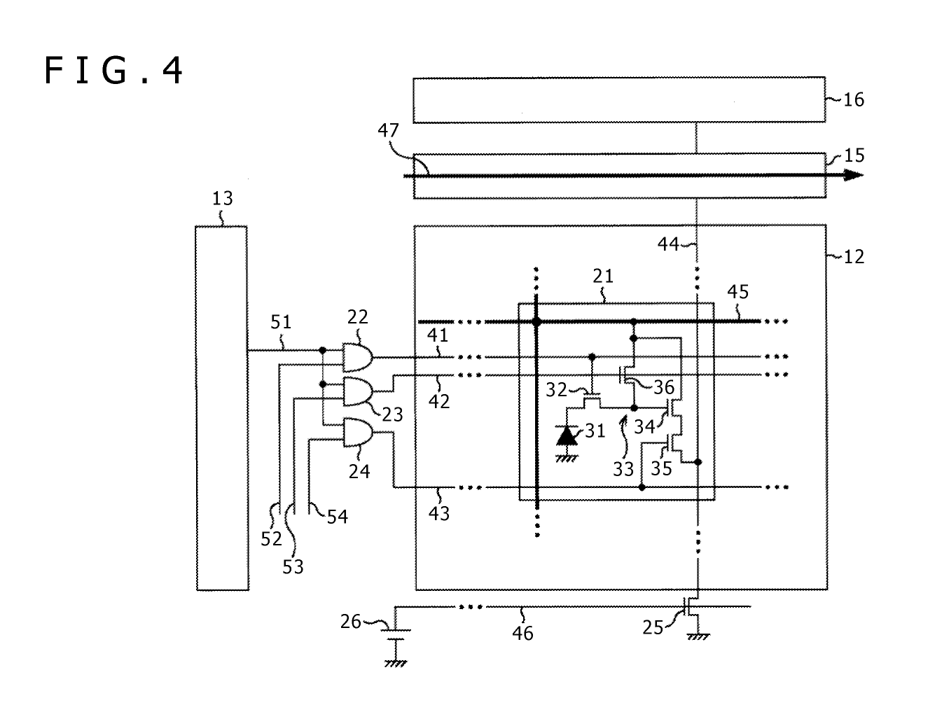

The pixel array section 12 has a plurality of pixels (for example, a pixel 21 in FIG. 4) arranged two-dimensionally. Each of the pixels has one or a plurality of photoelectric conversion elements. In addition, a plurality of pieces of signal wiring for supplying signals from the vertical driving circuit 13 to each pixel are connected to the pixel array section 12 on a row-by-row basis, and a plurality of pieces of signal wiring for outputting pixel signals from respective pixels to the CDS circuit 15 are connected to the pixel array section 12 on a column-by-column basis.

The vertical driving circuit 13 sequentially supplies signals for selecting the plurality of pixels possessed by the pixel array section 12 on a row-by-row basis via the signal wiring.

The shutter driving circuit 14 sequentially supplies driving signals for performing shutter driving to each row of the plurality of pixels possessed by the pixel array section 12. For example, the exposure time (charge accumulation time) of the pixels can be adjusted by adjusting intervals between the driving signals output from the shutter driving circuit 14 and the signals output from the vertical driving circuit 13.

The CDS circuit 15 reads out pixel signals from pixels of a row selected by a signal from the vertical driving circuit 13, and performs CDS processing. Specifically, the CDS circuit 15 obtains signals indicating pixel values from which the fixed pattern noise of the respective pixels is removed by obtaining differences between pixel signals corresponding to the levels of charges accumulated in the respective pixels and pixel signals of reset levels of the respective pixels. Then, the CDS circuit 15 sequentially outputs the obtained signals indicating the pixel values to the AGC 17 according to driving signals from the horizontal driving circuit 16.

The horizontal driving circuit 16 outputs the driving signals for selecting the pixels possessed by the pixel array section 12 in order in a column direction and outputting the signals indicating the pixel values to the CDS circuit 15.

The AGC 17 amplifies the signals indicating the pixel values which signals are supplied from the CDS circuit 15 with an appropriate gain, and outputs the amplified signals to the A/D converting section 18.

The A/D converting section 18 outputs pixel data obtained by converting the analog signals supplied from the AGC 17 into digital numerical values to the outside of the solid-state imaging element 11.

The timing generator 19 generates signals indicating timing necessary to drive the respective blocks of the solid-state imaging element 11 on the basis of a clock signal of a predetermined frequency, and supplies the signals to the respective blocks.

In FIG. 3, flows of signals output from pixels are indicated by arrows of thick lines. The signals output from the pixel array section 12 are subjected to CDS processing in the CDS circuit 15, thereafter amplified in the AGC 17, subjected to A/D conversion in the A/D converting section 18, and output to the outside.

Incidentally, FIG. 3 shows one example of configuration of the solid-state imaging element 11. A configuration in which the A/D converting section 18 is not provided within the solid-state imaging element 11 or a configuration in which an A/D converting section is provided for each column of pixels, for example, can be adopted. In addition, the solid-state imaging element 11 may have a plurality of output systems by being provided with one or more CDS circuits 15 or being provided with a plurality of AGCs 17 and A/D converting sections 18.

A pixel in the pixel array section 12 and a peripheral circuit will next be described with reference to FIG. 4.

As described above, the pixel array section 12 has a plurality of pixels arranged therein two-dimensionally. However, FIG. 4 shows one pixel 21 among the plurality of pixels, and does not show the other pixels for simplicity. As shown in FIG. 4, the peripheral circuit of the pixel array section 12 includes AND elements 22 to 24 arranged for each row of pixels 21, a transistor 25 disposed for each column of pixels 21, and a constant-potential source 26.

The pixel 21 includes a PD 31, a transfer transistor 32, an FD 33, an amplifying transistor 34, a selecting transistor 35, and a reset transistor 36. In addition, the pixel 21 is connected with transfer signal wiring 41, reset signal wiring 42, and selecting signal wiring 43 for supplying signals common to pixels 21 arranged in a row direction, and connected with pixel output wiring 44 for outputting a pixel signal to the CDS circuit 15. In addition, the pixel 21 is supplied with a predetermined power supply potential via power supply potential supplying wiring 45.

The PD 31 is a photoelectric conversion element for generating a charge by subjecting light applied to the pixel 21 to photoelectric conversion, and storing the charge.

The transfer transistor 32 transfers the charge stored in the PD 31 to the FD 33 according to a transfer signal supplied via the transfer signal wiring 41.

The FD 33 is a floating diffusion region formed at a point of connection between the transfer transistor 32 and the gate electrode of the amplifying transistor 34. The FD 33 temporarily stores the charge transferred from the PD 31 via the transfer transistor 32. That is, the potential of the gate electrode of the amplifying transistor 34 increases according to the charge stored in the FD 33.

The amplifying transistor 34 has a drain thereof connected to the power supply potential supplying wiring 45. The amplifying transistor 34 converts the charge stored in the FD 33 into a pixel signal having a level corresponding to the potential of the charge, and outputs the pixel signal.

The selecting transistor 35 is supplied with a selecting signal for selecting the pixel 21 to output the pixel signal via the selecting signal wiring 43. The selecting transistor 35 connects the amplifying transistor 34 to the pixel output wiring 44 according to the selecting signal.

The reset transistor 36 has a drain thereof connected to the power supply potential supplying wiring 45. The reset transistor 36 resets the charge stored in the FD 33 according to a reset signal supplied via the reset signal wiring 42.

The transistor 25 supplies a constant current to the pixel output wiring 44. That is, the constant current is supplied from the transistor 25 to the amplifying transistor 34 of the pixel 21 selected to output the pixel signal, whereby the amplifying transistor 34 operates as a source follower. Thus, a potential having a predetermined certain voltage difference from the gate potential of the amplifying transistor 34 appears in the pixel output wiring 44.

The constant-potential source 26 supplies a constant potential to the gate electrode of the transistor 25 via constant-potential supplying wiring 46 so that the transistor 25 operates in a saturation region to supply the constant current.

The AND element 22 has an output terminal connected to the gate electrode of the transfer transistor 32 via the transfer signal wiring 41. In addition, the AND element 22 has one input terminal connected to the output terminal of the vertical driving circuit 13 via signal wiring 51, and has another input terminal connected to a terminal for outputting the transfer signal in the form of a pulse according to driving timing via signal wiring 52.

The AND element 23 has an output terminal connected to the gate electrode of the reset transistor 36 via the reset signal wiring 42. In addition, the AND element 23 has one input terminal connected to the output terminal of the vertical driving circuit 13 via the signal wiring 51, and has another input terminal connected to a terminal for outputting the reset signal in the form of a pulse according to driving timing via signal wiring 53.

The AND element 24 has an output terminal connected to the gate electrode of the selecting transistor 35 via the selecting signal wiring 43. In addition, the AND element 24 has one input terminal connected to the output terminal of the vertical driving circuit 13 via the signal wiring 51, and has another input terminal connected to a terminal for outputting the selecting signal in the form of a pulse according to driving timing via signal wiring 54.

In the solid-state imaging element 11 having such a configuration, the transfer signal, the reset signal, and the selecting signal are supplied to the pixel 21 disposed in the row selected by the vertical driving circuit 13 via the transfer signal wiring 41, the reset signal wiring 42, and the selecting signal wiring 43, respectively.

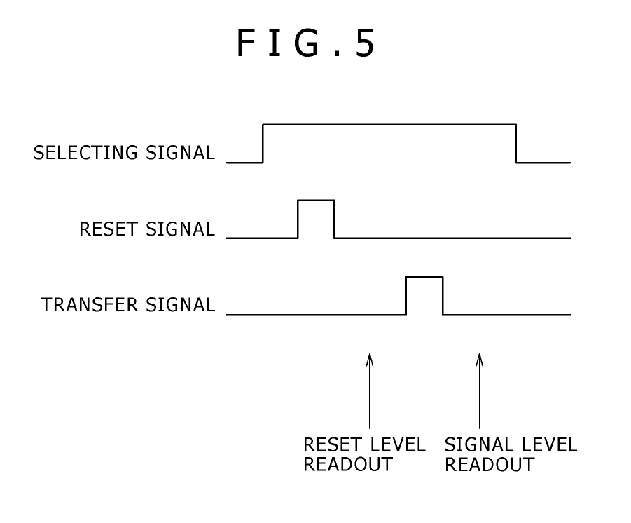

The driving signals supplied to the pixel 21 will next be described with reference to FIG. 5.

The selecting signal shown in FIG. 5 is supplied to the selecting transistor 35 via the selecting signal wiring 43. The reset signal is supplied to the reset transistor 36 via the reset signal wiring 42. The transfer signal is supplied to the transfer transistor 32 via the transfer signal wiring 41.

When timing of starting a readout period for reading out a pixel signal from the pixel 21 arrives, the selecting signal is set to a high level, and thus the selecting transistor 35 is set in a conducting state. The signal of the pixel 21 therefore becomes able to be output to the CDS circuit 15 via the pixel output wiring 44.

Thereafter, the reset signal is set to a high level, and thus the reset transistor 36 is set in a conducting state. A charge stored in the FD 33 is thereby reset. Then, the reset signal is set to a low level. The reset transistor 36 is thereby set in a non-conducting state to complete the reset. A pixel signal having a reset level is thereafter output to the CDS circuit 15.

Next, the transfer signal is set to a high level, and thereby the transfer transistor 32 is set in a conducting state. A charge stored in the PD 31 is thus transferred to the FD 33. Then, the transfer signal is set to a low level. The transfer transistor 32 is thereby set in a non-conducting state to complete the transfer of the charge. A pixel signal corresponding to the level of the charge stored in the FD 33 is thereafter output to the CDS circuit 15.

Thus, in the solid-state imaging element 11, the pixel signal of the reset level and the pixel signal corresponding to the level of the charge stored in the FD 33 are output to the CDS circuit 15. The CDS circuit 15 then performs CDS processing to thereby cancel a fixed pattern noise caused by variation in threshold voltage of the amplifying transistor 34 in each pixel 21 and the like.

In addition, the CDS circuit 15 outputs a signal indicating the pixel value of the pixel 21 in the column selected by the horizontal driving circuit 16 to the AGC 17 in FIG. 3 via horizontal signal wiring 47.

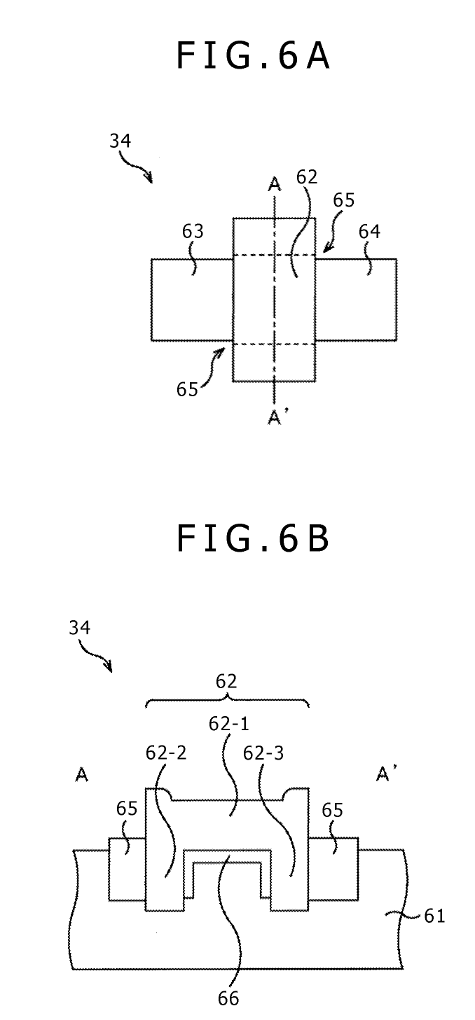

Next, FIGS. 6A and 6B are diagrams showing a first example of constitution of the amplifying transistor 34 possessed by the pixel 21. FIG. 6A shows an example of a planar constitution of the amplifying transistor 34. FIG. 6B shows an example of a constitution in section in a direction of width of the amplifying transistor 34 (section taken along a line A-A′ of FIG. 6A).

As shown in FIGS. 6A and 6B, the amplifying transistor 34 is constructed by forming a gate electrode 62, a source region 63, a drain region 64, and a channel region 66 in a silicon substrate 61. In addition, element isolation regions 65 for separating the amplifying transistor 34 from other elements such as the PD 31 and the like are formed at both ends of the gate electrode 62 in the direction of width of the amplifying transistor 34 (direction of the line A-A′ of FIG. 6A) so as to sandwich the amplifying transistor 34.

The gate electrode 62 includes a main body part 62-1 formed on the upper surface side of the silicon substrate 61 and projection parts 62-2 and 62-3 formed in the vicinity of both ends in a direction of width of the main body part 62-1 so as to protrude into the inside of the silicon substrate 61. That is, as shown in FIG. 6B, the bottom surface of the gate electrode 62 is formed such that a shape along the section in the direction of width of the amplifying transistor 34 is a U-shape having two parts at both ends thereof protruding into the silicon substrate 61.

The source region 63 and the drain region 64 are impurity regions formed by ion implantation of a high concentration impurity into the silicon substrate 61. The source region 63 is formed on one side in a direction of length of the amplifying transistor 34. The drain region 64 is formed on another side in the direction of length of the amplifying transistor 34.

The channel region 66 is a region serving as a path through which a current flows between the source region 63 and the drain region 64. The channel region 66 is formed along the shape of the bottom surface of the gate electrode 62. That is, the channel region 66 is formed on the bottom surface of the main body part 62-1 of the gate electrode 62 and side surfaces of the projection parts 62-2 and 62-3 of the gate electrode 62, and is formed such that the sectional shape of the channel region 66 is a U-shape.

In manufacturing the amplifying transistor 34, grooves are first dug on both sides in the direction of width of the amplifying transistor 34 at a time of formation of the element isolation regions 65, and ion implantation for forming the channel region 66 is performed from an oblique direction in a state of the grooves at both ends being open. The channel region 66 is thereby formed in a part along the bottom surface of the main body part 62-1 of the gate electrode 62 and parts along the side surfaces of the projection parts 62-2 and 62-3 of the gate electrode 62. Then, after a gate oxide film not shown in the figures is formed, polysilicon is filled into the grooves at both ends of the amplifying transistor 34 to form the projection parts 62-2 and 62-3, and further polysilicon is laminated to form the main body part 62-1.

Thereby, the channel region 66 is formed in the part along the bottom surface of the main body part 62-1 of the gate electrode 62, and also formed in the parts along the side surfaces of the projection parts 62-2 and 62-3 of the gate electrode 62. Thus, effective channel width (W-length) of the amplifying transistor 34 can be increased by an amount corresponding to the formations of the channel region 66 in the parts along the side surfaces of the projection parts 62-2 and 62-3 in the amplifying transistor 34 without an increase in area of the region in which the amplifying transistor 34 is formed. Therefore, the amplifying transistor 34 can increase mutual conductance, and improve the speed of readout of the pixel signal in the solid-state imaging element 11, for example.

In addition, in the amplifying transistor 34, the channel region 66 and the element isolation regions 65 are formed so as not to be in contact with each other because of the projection parts 62-2 and 62-3 of the gate electrode 62. Thus, the occurrence of noise can be suppressed. That is, when edges of the element isolation regions 65 are used as a channel region, the contacting parts become a source of noise, whereas the amplifying transistor 34 has a structure without a source of noise formed therein.

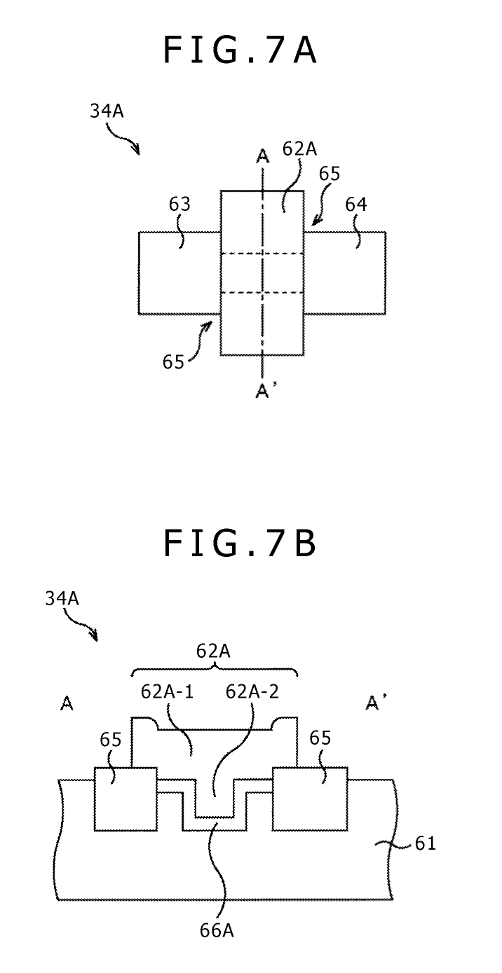

An amplifying transistor 34A as a second example of constitution will next be described with reference to FIGS. 7A and 7B. FIG. 7A shows an example of a planar constitution of the amplifying transistor 34A. FIG. 7B shows an example of a constitution in section in a direction of width of the amplifying transistor 34A (section taken along a line A-A′ of FIG. 7A).

Incidentally, in FIGS. 7A and 7B, constituent elements similar to those of the amplifying transistor 34 of FIGS. 6A and 6B are identified by the same reference symbols, and detailed description thereof will be omitted. Specifically, the amplifying transistor 34A is similar to the amplifying transistor 34 of FIGS. 6A and 6B in that the amplifying transistor 34A has a source region 63 and a drain region 64 formed therein, and is isolated by element isolation regions 65. On the other hand, a gate electrode 62A and a channel region 66A in the amplifying transistor 34A are formed so as to have different shapes from those of the gate electrode 62 and the channel region 66 in the amplifying transistor 34.

The gate electrode 62A includes a main body part 62A-1 formed on the upper surface side of a silicon substrate 61 and a projection part 62A-2 formed on substantially the center of the main body part 62A-1 so as to protrude into the inside of the silicon substrate 61.

The projection part 62A-2 is formed so as to extend along a direction of length of the gate electrode 62A by digging one groove along the direction of length of the gate electrode 62A in the silicon substrate 61, and filling polysilicon into the groove. Thereby, as shown in FIG. 7B, the bottom surface of the gate electrode 62A is formed such that a shape along a section in a direction of width of the amplifying transistor 34A is a T-shape whose center protrudes into the silicon substrate 61.

Therefore, the channel region 66A formed along the shape of the bottom surface of the gate electrode 62A is formed on the bottom surface of the main body part 62A-1 of the gate electrode 62A and the bottom surface and side surfaces of the projection part 62A-2 of the gate electrode 62A.

Thus, effective channel width (W-length) of the amplifying transistor 34A can be increased by an amount corresponding to the formations of the channel region 66A in the parts along the side surfaces of the projection part 62A-2 of the gate electrode 62A in the amplifying transistor 34A. The amplifying transistor 34A can thereby increase mutual conductance.

Incidentally, in the channel region 66A, though both ends of the channel region 66A are formed so as to be in contact with the element isolation regions 65, the projection part 62A-2 of the gate electrode 62A is formed at a position separated from the element isolation regions 65. This can suppress effects on other adjacent elements which effects are feared to be produced by forming the projection part 62A-2.

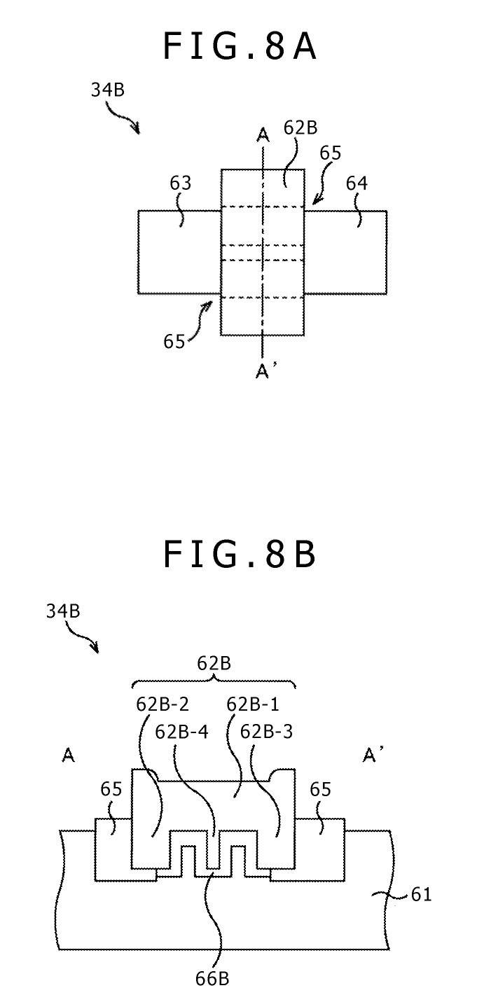

An amplifying transistor 34B as a third example of constitution will next be described with reference to FIGS. 8A and 8B. FIG. 8A shows an example of a planar constitution of the amplifying transistor 34B. FIG. 8B shows an example of a constitution in section in a direction of width of the amplifying transistor 34B (section taken along a line A-A′ of FIG. 8A).

Incidentally, in FIGS. 8A and 8B, constituent elements similar to those of the amplifying transistor 34 of FIGS. 6A and 6B are identified by the same reference symbols, and detailed description thereof will be omitted. Specifically, the amplifying transistor 34B is similar to the amplifying transistor 34 of FIGS. 6A and 6B in that the amplifying transistor 34B has a source region 63 and a drain region 64 formed therein, and is isolated by element isolation regions 65. On the other hand, a gate electrode 62B and a channel region 66B in the amplifying transistor 34B are formed so as to have different shapes from those of the gate electrode 62 and the channel region 66 in the amplifying transistor 34.

The gate electrode 62B includes a main body part 62B-1 formed on the upper surface side of a silicon substrate 61, projection parts 62B-2 and 62B-3 formed in the vicinity of both ends in a direction of width of the main body part 62B-1 so as to protrude into the inside of the silicon substrate 61, and a projection part 62B-4 formed on substantially the center of the main body part 62B-1 so as to protrude into the inside of the silicon substrate 61.

The projection parts 62B-2 to 62B-4 are formed so as to extend along a direction of length of the gate electrode 62B by digging three grooves along the direction of length of the gate electrode 62B in the silicon substrate 61, and filling polysilicon into the grooves. That is, as shown in FIG. 8B, the bottom surface of the gate electrode 62B is formed such that a shape along a section in a direction of width of the amplifying transistor 34B is an E-shape having three parts as both ends and the center thereof protruding into the silicon substrate 61.

Therefore, the channel region 66B formed along the shape of the bottom surface of the gate electrode 62B is formed on the bottom surface of the main body part 62B-1 of the gate electrode 62B and the bottom surfaces and side surfaces of the projection parts 62B-2 to 62B-4 of the gate electrode 62B.

Thus, effective channel width (W-length) of the amplifying transistor 34B can be increased by an amount corresponding to the formations of the channel region 66B in the parts along the side surfaces of the projection parts 62B-2 to 62B-4 of the gate electrode 62B in the amplifying transistor 34B. The amplifying transistor 34B can thereby increase mutual conductance.

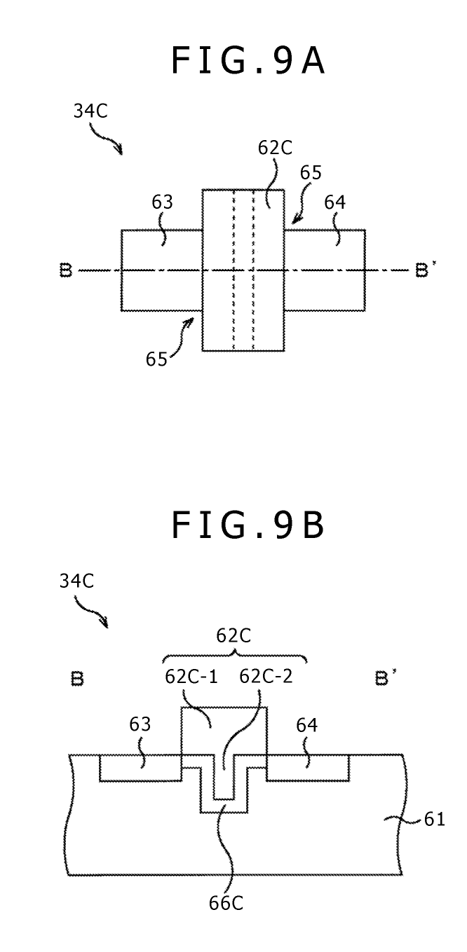

An amplifying transistor 34C as a fourth example of constitution will next be described with reference to FIGS. 9A and 9B. FIG. 9A shows an example of a planar constitution of the amplifying transistor 34C. FIG. 9B shows an example of a constitution in section in a direction of length of the amplifying transistor 34C (section taken along a line B-B′ of FIG. 9A).

Incidentally, in FIGS. 9A and 9B, constituent elements similar to those of the amplifying transistor 34 of FIGS. 6A and 6B are identified by the same reference symbols, and detailed description thereof will be omitted. Specifically, the amplifying transistor 34C is similar to the amplifying transistor 34 of FIGS. 6A and 6B in that the amplifying transistor 34C has a source region 63 and a drain region 64 formed therein, and is isolated by element isolation regions 65. On the other hand, a gate electrode 62C and a channel region 66C in the amplifying transistor 34C are formed so as to have different shapes from those of the gate electrode 62 and the channel region 66 in the amplifying transistor 34.

The gate electrode 62C includes a main body part 62C-1 formed on the upper surface side of a silicon substrate 61 and a projection part 62C-2 formed on substantially the center of the main body part 62C-1 so as to protrude into the inside of the silicon substrate 61.

The projection part 62C-2 is formed so as to extend along a direction of width of the gate electrode 62C by digging one groove along the direction of width of the gate electrode 62C in the silicon substrate 61, and filling polysilicon into the groove. That is, as shown in FIG. 9B, the bottom surface of the gate electrode 62C is formed such that a shape along a section in a direction of length of the amplifying transistor 34C is a T-shape whose center protrudes into the silicon substrate 61.

Therefore, the channel region 66C formed along the shape of the bottom surface of the gate electrode 62C is formed on the bottom surface of the main body part 62C-1 of the gate electrode 62C and the bottom surface and side surfaces of the projection part 62C-2 of the gate electrode 62C.

Thus, effective channel length (L-length) of the amplifying transistor 34C can be increased by an amount corresponding to the formations of the channel region 66C in the parts along the side surfaces of the projection part 62C-2 of the gate electrode 62C in the amplifying transistor 34C. The amplifying transistor 34C can thereby suppress the occurrence of noise.

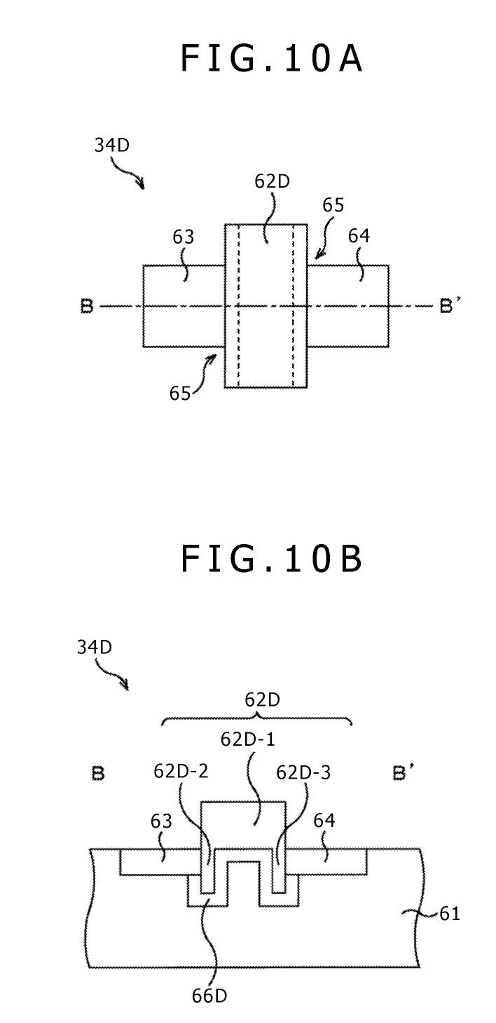

An amplifying transistor 34D as a fifth example of constitution will next be described with reference to FIGS. 10A and 10B. FIG. 10A shows an example of a planar constitution of the amplifying transistor 34D. FIG. 10B shows an example of a constitution in section in a direction of length of the amplifying transistor 34D (section taken along a line B-B′ of FIG. 10A).

Incidentally, in FIGS. 10A and 10B, constituent elements similar to those of the amplifying transistor 34 of FIGS. 6A and 6B are identified by the same reference symbols, and detailed description thereof will be omitted. Specifically, the amplifying transistor 34D is similar to the amplifying transistor 34 of FIGS. 6A and 6B in that the amplifying transistor 34D has a source region 63 and a drain region 64 formed therein, and is isolated by element isolation regions 65. On the other hand, a gate electrode 62D and a channel region 66D in the amplifying transistor 34D are formed so as to have different shapes from those of the gate electrode 62 and the channel region 66 in the amplifying transistor 34.

The gate electrode 62D includes a main body part 62D-1 formed on the upper surface side of a silicon substrate 61 and projection parts 62D-2 and 62D-3 formed so as to protrude into the inside of the silicon substrate 61 in the direction of length of the main body part 62D-1.

The projection parts 62D-2 and 62D-3 are formed so as to extend along a direction of width of the gate electrode 62D by digging two grooves along the direction of width of the gate electrode 62D in the silicon substrate 61, and filling polysilicon into the grooves. Thereby, as shown in FIG. 10B, the bottom surface of the gate electrode 62D is formed such that a shape along a section in a direction of length of the amplifying transistor 34D is a U-shape having both ends protruding into the silicon substrate 61.

Therefore, the channel region 66D formed along the shape of the bottom surface of the gate electrode 62D is formed on the bottom surface of the main body part 62D-1 of the gate electrode 62D and the bottom surfaces and side surfaces of the projection parts 62D-2 and 62D-3 of the gate electrode 62D.

Thus, effective channel length (L-length) of the amplifying transistor 34D can be increased by an amount corresponding to the formations of the channel region 66D in the parts along the side surfaces of the projection parts 62D-2 and 62D-3 of the gate electrode 62D in the amplifying transistor 34D. The amplifying transistor 34D can thereby suppress the occurrence of noise.

In addition, it is assumed that the vicinities of the source region and the drain region of an amplifying transistor tend to be affected by stress caused by side walls formed along the side surfaces of a gate electrode, for example, and thus tend to become a source of noise. On the other hand, the projection parts 62D-2 and 62D-3 formed in the amplifying transistor 34D can suppress effects of noise occurring at the end parts of the source region 63 and the drain region 64.

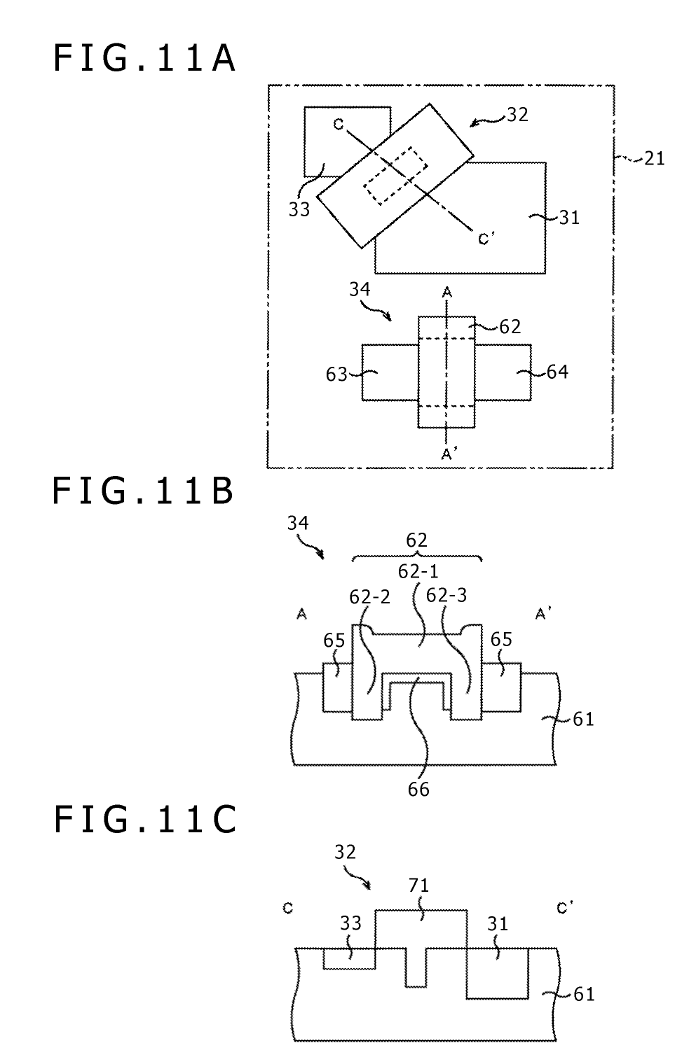

An example of constitution of the pixel 21 will next be described with reference to FIGS. 11A, 11B, and 11C. FIG. 11A shows an example of a planar constitution of the pixel 21. FIG. 11B shows an example of a constitution in section in a direction of width of the amplifying transistor 34 (section taken along a line A-A′ of FIG. 11A). FIG. 11C shows an example of a constitution in section in a direction of length of the transfer transistor 32 (section taken along a line C-C′ of FIG. 11A).

As shown in FIGS. 11A, 11B, and 11C, in the pixel 21, the transfer transistor 32 is formed between the PD 31 and the FD 33, and the transfer transistor 32 has a gate electrode 71. As shown in FIG. 11C, the gate electrode 71 is formed such that a part of the gate electrode 71 is buried in a silicon substrate 61. Incidentally, a buried gate formed as in the transfer transistor 32 is described in detail in Japanese Patent Laid-Open No. 2010-114274 already filed by the present applicant.

Specifically, in the pixel 21, the transfer transistor 32 having the gate electrode 71 a part of which is buried in the silicon substrate 61 and the amplifying transistor 34 having a gate electrode 62 whose projection parts 62-2 and 62-3 are buried in the silicon substrate 61 are used in combination with each other. Thus, in a process of manufacturing the pixel 21, digging for the amplifying transistor 34 can also be performed in parallel with digging for the transfer transistor 32.

In addition, ion implantation for forming a channel region 66 in the amplifying transistor 34 after the digging is performed with the dug part in the transfer transistor 32 covered so that ion implantation is not performed into the transfer transistor 32. Then, the gate electrode 71 of the transfer transistor 32 and the gate electrode 62 of the amplifying transistor 34 are formed in parallel with each other.

Thus, a dug structure can be adopted for the amplifying transistor 34 with a minimum process addition to a process of manufacturing the transfer transistor 32 having a dug structure.

Incidentally, while the constitution of the amplifying transistor 34 of FIGS. 6A and 6B is used in the pixel 21 of FIGS. 11A to 11C, the constitutions of the amplifying transistors 34A to 34D described with reference to FIGS. 7A to 10B, for example, may be used.

In addition, in relation to the constitution of the amplifying transistor 34, the number of projection parts 62-2 possessed by the gate electrode 62 and the direction in which the projection parts 62-2 are formed (for example, the width direction, the length direction, or the like), for example, are not limited to the foregoing embodiments. That is, a gate electrode 62 having one, two, or three or more projection parts 62-2 may be formed, and a plurality of projection parts 62-2 extending along the width direction and the length direction of the amplifying transistor 34 may be used in combination with each other. In addition, the projection parts 62-2 may be formed so as to be shallower or deeper than the element isolation regions 65.

Further, the dug structure of the amplifying transistor 34 can be applied to the other transistors forming the pixel 21 such as the selecting transistor 35 and the reset transistor 36, for example. In addition, in relation to the sizes of these transistors, when a certain transistor is reduced in size, the sizes of the other transistors may be correspondingly increased.

Concrete embodiments to which the present technology is applied will hereinafter be described in detail with reference to the drawings.

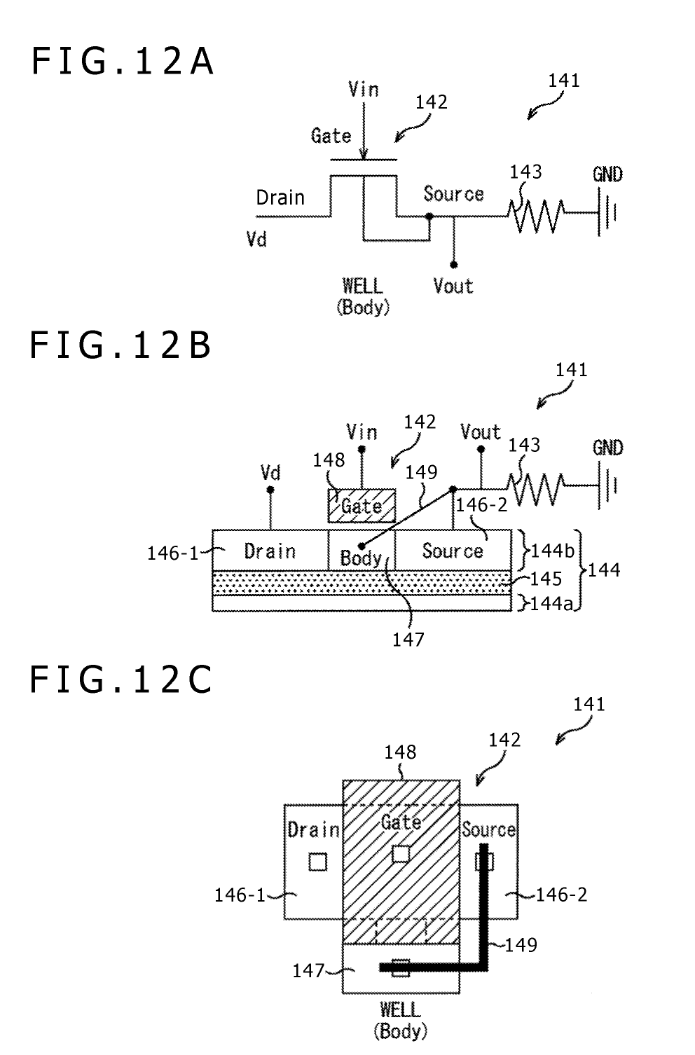

FIGS. 12A, 12B, and 12C are diagrams showing an example of constitution of a first embodiment of an amplifying circuit to which the present technology is applied.

FIG. 12A is a circuit diagram of the amplifying circuit. FIG. 12B shows an example of a sectional constitution of a transistor forming the amplifying circuit. FIG. 12C shows an example of a planar constitution of the transistor forming the amplifying circuit.

As shown in FIG. 12A, in the amplifying circuit 141, the source terminal (Source) of the transistor 142 is grounded (GND) via a resistance 143. Then, in the amplifying circuit 141, the source terminal of the transistor 142 and a well (WELL (Body)) are electrically connected to each other.

In addition, as shown in FIG. 12B, the transistor 142 of the amplifying circuit 141 is formed in a partially depleted type SOI (Silicon On Insulator) substrate 144. The SOI substrate 144 has a structure formed by inserting a silicon oxide film 145 (BOX layer) between a silicon substrate layer 144a and a surface silicon layer 144b. The silicon oxide film 145 insulates the silicon substrate layer 144a and the surface silicon layer 144b from each other.

An N-type region 146-1 serving as a drain of the transistor 142 and an N-type region 146-2 serving as a source of the transistor 142 are formed in the surface silicon layer 144b of the SOI substrate 144. A P-type region between the N-type region 146-1 and the N-type region 146-2 is a well (Body) 147. The N-type region 146-1 and the N-type region 146-2 in the surface silicon layer 144b are formed from the surface of the SOI substrate 144 to an interface with the silicon oxide film 145. Thus, the well 147 is surrounded by the N-type region 146-1, the N-type region 146-2, and the silicon oxide film 145, and is electrically independent of the silicon substrate layer 144a under the silicon oxide film 145 and the wells 147 of other transistors 142.

A gate electrode 148 of the transistor 142 is formed on the surface of the SOI substrate 144 with a gate insulating film not shown in the figures interposed between the gate electrode 148 and the surface of the SOI substrate 144, and is disposed at a position between the N-type regions 146-1 and 146-2, that is, a position corresponding to the well 147.

In the transistor 142, the N-type region 146-2 serving as the source of the transistor 142 and the well 147 are electrically connected to each other by wiring 149. The wiring 149 is formed in a wiring layer laminated on the surface side of the SOI substrate 144, and is disposed in a layout as shown in FIG. 12C, for example.

Incidentally, in addition to the use of the wiring 149, a silicided region, for example, can be used for the electric connection of the N-type region 146-2 to the well 147.

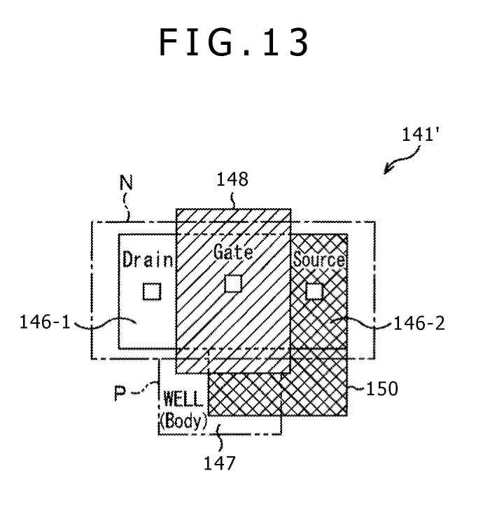

FIG. 13 shows an amplifying circuit 141′ as an example of modification of the first embodiment. A crosshatched region in the amplifying circuit 141′ is a silicided region 150 formed on the surface of an SOI substrate 144. The silicided region 150 electrically connects (joins) an N-type region 146-2 and a well 147 to each other. Incidentally, in FIG. 13, a region N indicated by alternate long and short dashed lines is implanted with N-type ions when the N-type regions 146-1 and 146-2 are formed, and a region P indicated by a chain double-dashed line is implanted with P-type ions.

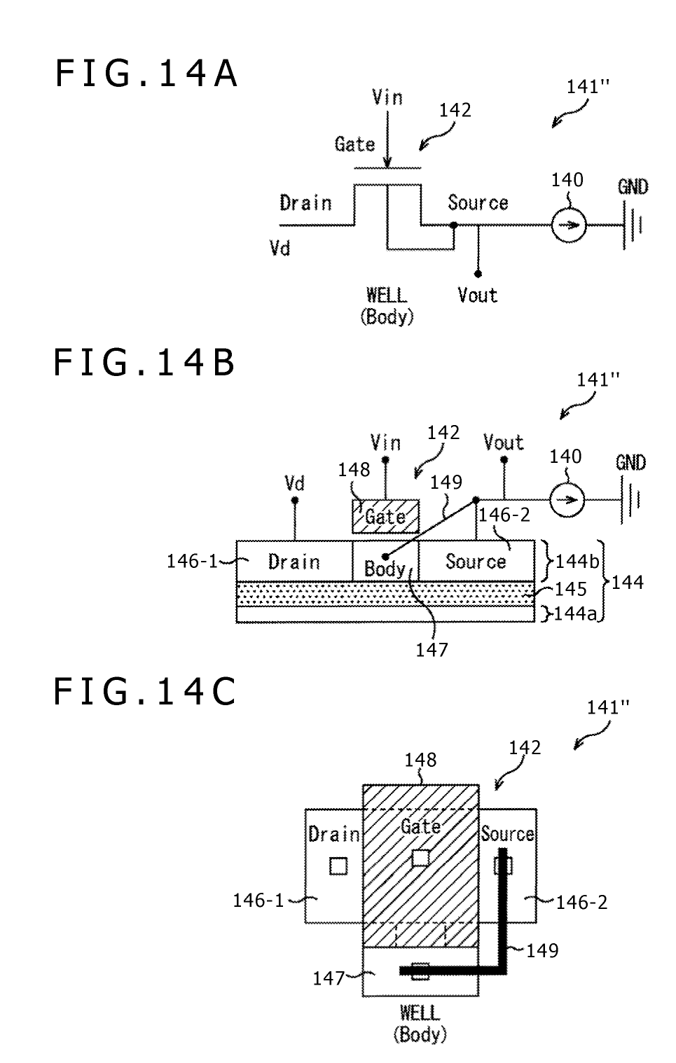

Incidentally, while FIGS. 12A to 12C show the amplifying circuit 141 in the example of constitution in which the resistance 143 is connected to the source terminal of the transistor 142, a constitution using a constant-current source may be adopted in place of the resistance 143. Specifically, as shown in FIGS. 14A and 14B, an amplifying circuit 141″ can be formed such that the source terminal of a transistor 142 is grounded via a constant-current source 140.

In the amplifying circuit 141 using the thus formed transistor 142, a drain voltage Vd is supplied to the drain of the transistor 142, and a current corresponding to an input voltage Vin applied to the gate electrode 148 flows via the resistance 143. Accordingly, an output voltage Vout obtained by amplifying the input voltage Vin with a predetermined amplification factor is output from the source of the transistor 142.

At this time, in the amplifying circuit 141, because the N-type region 146-2 serving as the source of the transistor 142 and the well 147 are electrically connected to each other, the gain (degree of modulation) of the output voltage Vout can be brought close to one. That is, in the amplifying circuit 141, the well 147 can be made electrically independent of the silicon substrate layer 144a by forming the transistor 142 using the SOI substrate 144, and therefore the N-type region 146-2 and the well 147 can be electrically connected to each other. That is, the gain of an output voltage Vout in an amplifying circuit in related art is about 0.8 to 0.85, for example, due to a loss of gain caused by a substrate bias effect.

On the other hand, in the amplifying circuit 141, no reverse bias is applied between the N-type region 146-2 and the well 147. Therefore, the substrate bias effect does not occur, and a loss of gain can be avoided. The gain of the output voltage Vout can thus be brought infinitely close to one. Thus, the amplifying circuit 141 can obtain an excellent gain closer to one than in related art, and a loss of gain in the amplifying circuit 141 can be reduced.

Further, in the amplifying circuit 141, because the SOI substrate 144 is used, a need to form different wells is eliminated, and the transistor 142 can be formed in a minimum area. In the amplifying transistors of constitutions in which different wells are formed as disclosed in Patent Documents 2 and 3, a source voltage is applied to a well, so that a large area is required to maintain a well withstand voltage. As compared with such constitutions in which different wells are formed, the transistor 142 in the amplifying circuit 141 can be reduced in area because the surface silicon layer 144b is insulated from the silicon substrate layer 144a by the silicon oxide film 145.

Incidentally, the transistor 142 is manufactured by a manufacturing method that forms the N-type regions 146-1 and 146-2 in the surface silicon layer 144b of the SOI substrate 144 from the surface of the surface silicon layer 144b to the silicon oxide film 145, forms the gate electrode 148 on the surface side of the SOI substrate 144, and connects the well 147 and the N-type region 146-2 to each other by the wiring 149 or the silicided region 150.

Conversion efficiency can be greatly improved by applying the transistor 142 of such a constitution to pixels of an imaging element.

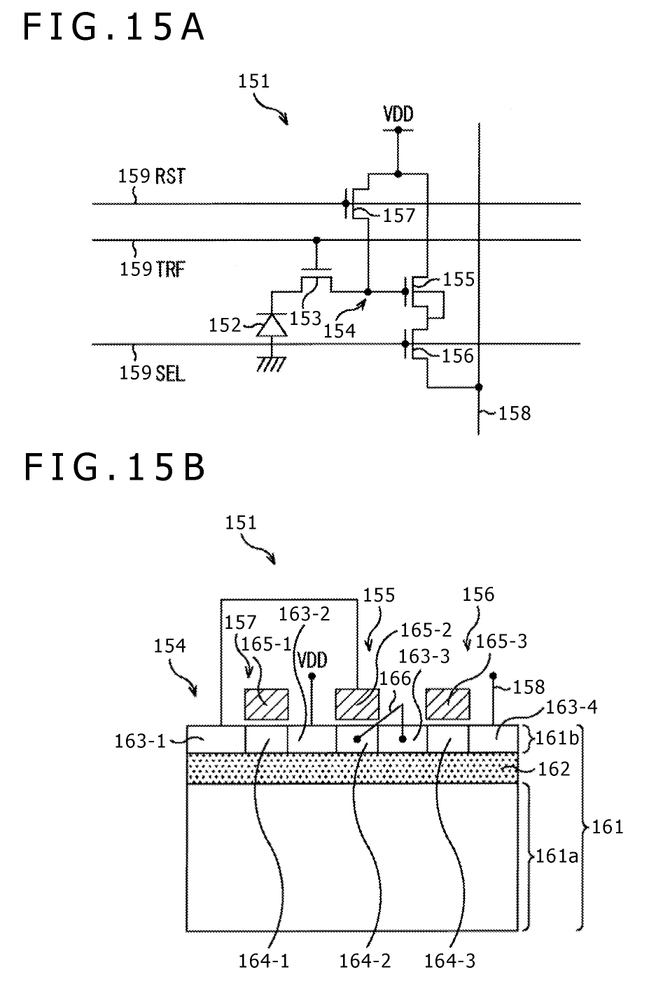

A first example of constitution of a pixel will next be described with reference to FIGS. 15A and 15B. FIG. 15A is a circuit diagram of the pixel. FIG. 15B shows a part of an example of a sectional constitution of transistors forming the pixel.

As shown in FIG. 15A, the pixel 151 includes a PD 152, a transfer transistor 153, an FD 154, an amplifying transistor 155, a selecting transistor 156, and a reset transistor 157. In addition, the pixel 151 is connected with a vertical signal line 158 for outputting a pixel signal from the pixel 151, and is connected with horizontal signal lines 159TRF, 159SEL, and 159RST for supplying signals for driving the pixel 151.

The PD 152 is a photoelectric conversion section. The PD 152 receives light applied to the pixel 151, generates a charge corresponding to the light amount of the light, and stores the charge.

The transfer transistor 153 is driven according to a transfer signal supplied via the horizontal signal line 159TRF. When the transfer transistor 153 is turned on, the charge stored in the PD 152 is transferred to the FD 154.

The FD 154 is a floating diffusion region having a predetermined capacitance formed at a point of connection between the source terminal of the transfer transistor 153 and the gate electrode of the amplifying transistor 155. The FD 154 stores the charge transferred from the PD 152 via the transfer transistor 153.

The drain terminal of the amplifying transistor 155 is connected to a power supply potential VDD. The charge stored in the FD 154 is applied to the gate electrode of the amplifying transistor 155. The amplifying transistor 155 outputs a pixel signal having a level corresponding to the charge from a source terminal. The source terminal and the well of the amplifying transistor 155 are electrically connected to each other. The amplifying transistor 155 has the constitution of the transistor 142 described with reference to FIGS. 12A to 12C.

The selecting transistor 156 is driven according to a selecting signal supplied via the horizontal signal line 159SEL. When the selecting transistor 156 is turned on, the pixel signal output from the amplifying transistor 155 becomes able to be read out from the vertical signal line 158 via the selecting transistor 156.

The reset transistor 157 is driven according to a reset signal supplied via the horizontal signal line 159RST. When the reset transistor 157 is turned on, the charge stored in the FD 154 is discharged to the power supply potential VDD via the reset transistor 157. The FD 154 is thereby reset to the level of the power supply potential VDD.

Incidentally, while the pixel 151 is configured to be selected via the selecting transistor 156, a circuit configuration from which the selecting transistor 156 is omitted (so-called three-transistor configuration) can be adopted.

In addition, as shown in FIG. 15B, the pixel 151 is formed in an SOI substrate 161.

The SOI substrate 161 has a structure including a silicon oxide film 162 inserted between a silicon substrate layer 161a and a surface silicon layer 161b. The silicon oxide film 162 insulates the silicon substrate layer 161a and the surface silicon layer 161b from each other.

N-type regions 163-1 to 163-4 are formed in the surface silicon layer 161b of the SOI substrate 161. P-type regions surrounded by the silicon oxide film 162 and the N-type regions 163-1 to 163-4 are wells 164-1 to 164-3. In addition, gate electrodes 165-1 to 165-3 are formed on the surface of the SOI substrate 161 with a gate insulating film not shown in the figures interposed between the gate electrodes 165-1 to 165-3 and the surface of the SOI substrate 161.

The gate electrode 165-1 forming the reset transistor 157 is disposed at a position between the N-type regions 163-1 and 163-2, that is, a position corresponding to the well 164-1. That is, the reset transistor 157 is formed with the N-type region 163-1 as a source and with the N-type region 163-2 as a drain. In addition, the N-type region 163-1 forms the FD 154.

The gate electrode 165-3 forming the selecting transistor 156 is disposed at a position between the N-type regions 163-3 and 163-4, that is, a position corresponding to the well 164-3. That is, the selecting transistor 156 is formed with the N-type region 163-3 as a drain and with the N-type region 163-4 as a source. In addition, the N-type region 163-4 is connected with the vertical signal line 158.

The gate electrode 165-2 forming the amplifying transistor 155 is disposed at a position between the N-type regions 163-2 and 163-3, that is, a position corresponding to the well 164-2. That is, the amplifying transistor 155 is formed with the N-type region 163-2 as a drain and with the N-type region 163-3 as a source. In addition, the gate electrode 165-2 of the amplifying transistor 155 is connected with the N-type region 163-1 forming the FD 154.

The N-type region 163-3 forming the source of the amplifying transistor 155 and the well 164-2 are electrically connected to each other by wiring 166. That is, the amplifying transistor 155 in the pixel 151 has the constitution of the transistor 142 described with reference to FIGS. 12A to 12C.

The pixel 151 is thus formed. The amplifying transistor 155 can obtain a gain close to one. Therefore, conversion efficiency can be greatly improved. In addition, a reduction in FD diffusion capacitance of the reset transistor 157 can also improve conversion efficiency greatly. Thus, better characteristics can be obtained.

Further, because the SOI substrate 161 is used, the amplifying transistor 155 can be formed in a minimum area, as described above. It is therefore possible to secure an area for the PD 152, and improve the S/N ratio (Signal to Noise ratio) of the pixel 151. In addition, the threshold value of the amplifying transistor 155 is not determined by the concentration of the well 164-2. Thus, a degree of freedom of adjustment of the threshold value is improved, and adjustment can be made so as to obtain linearity of an output signal as an imaging characteristic of the pixel 151.

The pixel 151 can therefore provide better characteristics than in related art.

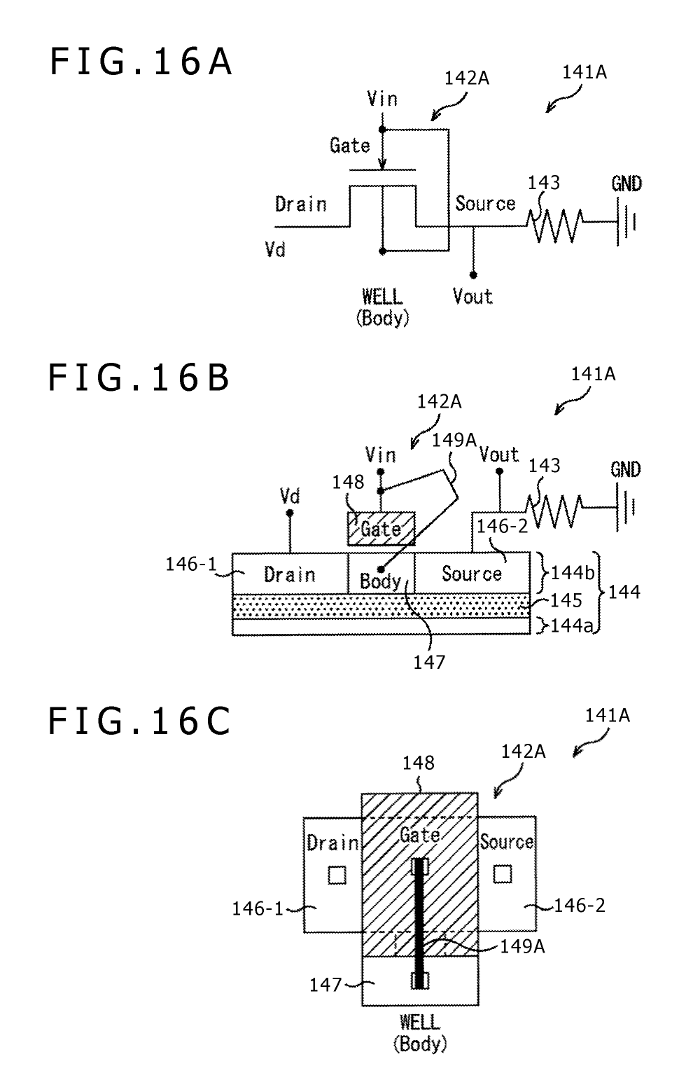

FIGS. 16A to 16C are diagrams showing an example of constitution of a second embodiment of the amplifying circuit to which the present technology is applied.

FIG. 16A is a circuit diagram of the amplifying circuit. FIG. 16B shows an example of a sectional constitution of a transistor forming the amplifying circuit. FIG. 16C shows an example of a planar constitution of the transistor forming the amplifying circuit. Incidentally, in FIGS. 16A to 16C, constituent elements similar to those of the amplifying circuit 141 of FIGS. 12A to 12C are identified by the same reference symbols, and detailed description thereof will be omitted.

As shown in FIG. 16A, in the amplifying circuit 141A, the source terminal of the transistor 142A is grounded (GND) via a resistance 143. The amplifying circuit 141A is different from the amplifying circuit 141 of FIGS. 12A to 12C in that the well and the gate electrode of the transistor 142A are electrically connected to each other.

That is, as shown in FIG. 16B and FIG. 16C, the transistor 142A forming the amplifying circuit 141A is formed with the well 147 and the gate electrode 148 electrically connected to each other by wiring 149A.

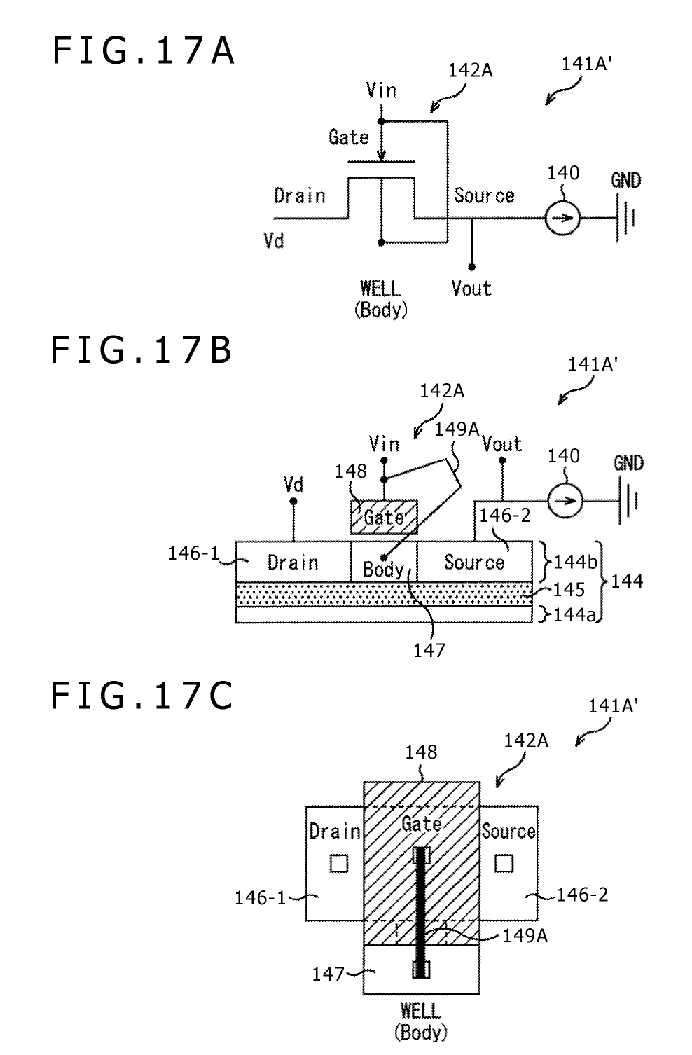

In addition, while FIGS. 16A to 16C show the amplifying circuit 141A in the example of constitution in which the resistance 143 is connected to the source terminal of the transistor 142A, a constitution using a constant-current source may be adopted in place of the resistance 143. Specifically, as shown in FIGS. 17A and 17B, an amplifying circuit 141A′ can be formed such that the source terminal of a transistor 142A is grounded via a constant-current source 140.

Also, in the amplifying circuit 141A using the thus formed transistor 142A, as in the above-described amplifying circuit 141, the gain of an output voltage Vout can be brought close to one, and a loss in the amplifying circuit 141A can be reduced.

Incidentally, the transistor 142A is manufactured by a manufacturing method that forms N-type regions 146-1 and 146-2 in the surface silicon layer 144b of an SOI substrate 144 from the surface of the surface silicon layer 144b to a silicon oxide film 145, forms the gate electrode 148 on the surface side of the SOI substrate 144, and connects the well 147 and the gate electrode 148 to each other by the wiring 149A.

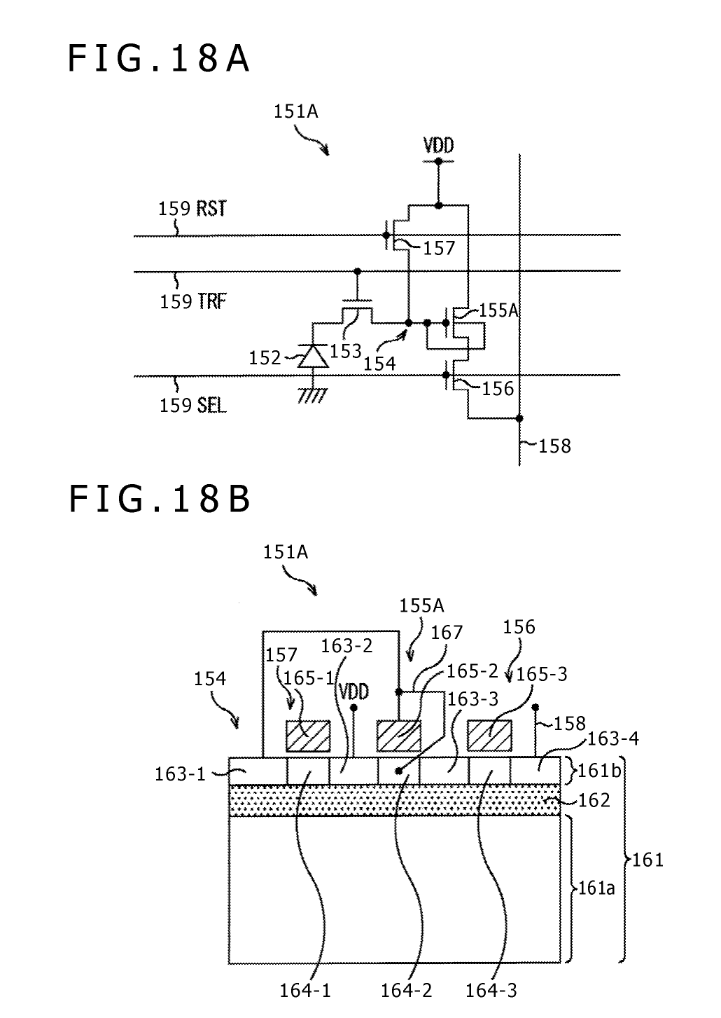

A second example of constitution of a pixel will next be described with reference to FIGS. 18A and 18B. FIG. 18A is a circuit diagram of the pixel. FIG. 18B shows a part of an example of a sectional constitution of transistors forming the pixel. Incidentally, in FIGS. 18A and 18B, constituent elements similar to those of the pixel 151 of FIGS. 15A and 15B are identified by the same reference symbols, and detailed description thereof will be omitted.

As shown in FIG. 18A, the pixel 151A includes a PD 152, a transfer transistor 153, an FD 154, an amplifying transistor 155A, a selecting transistor 156, and a reset transistor 157. In addition, the pixel 151A is connected with a vertical signal line 158, and is connected with horizontal signal lines 159TRF, 159SEL, and 159RST.

The amplifying transistor 155A in the pixel 151A has the constitution of the transistor 142A described with reference to FIGS. 16A to 16C with the well 164-2 and the gate electrode 165-2 of the amplifying transistor 155A electrically connected to each other. That is, whereas the pixel 151 of FIGS. 15A and 15B is formed with the well 164-2 and the N-type region 163-3 (source) of the amplifying transistor 155 connected to each other by the wiring 166, the pixel 151A is formed with the well 164-2 and the gate electrode 165-2 of the amplifying transistor 155A connected to each other by wiring 167.

In the thus formed pixel 151A, the amplifying transistor 155A can obtain a gain close to one. Therefore, as in the pixel 151, conversion efficiency can be greatly improved, and better characteristics can be obtained.

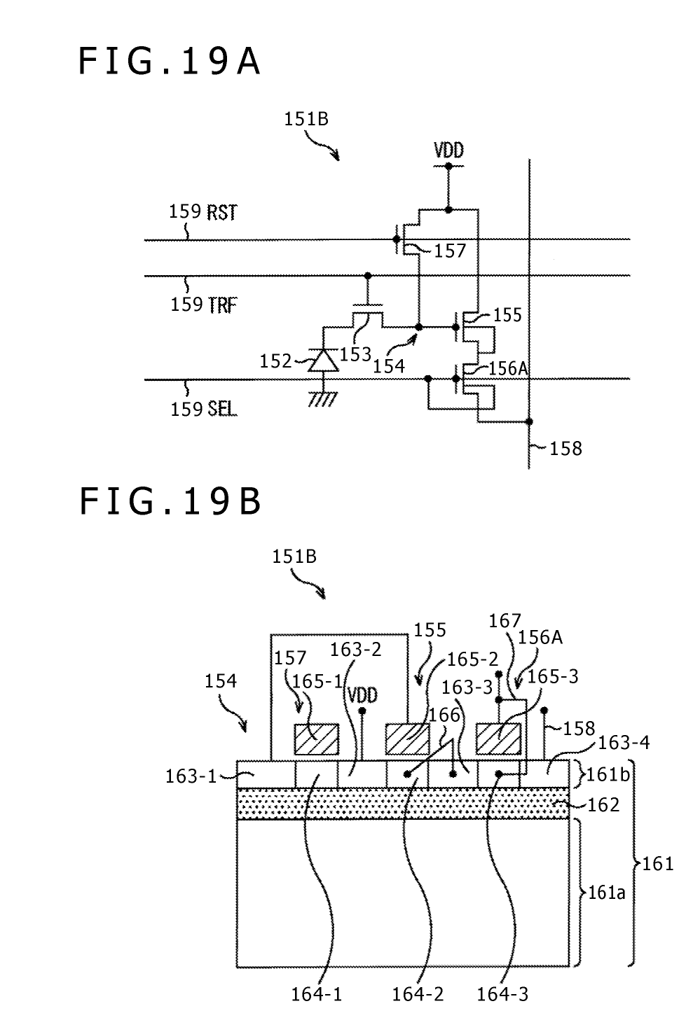

A third example of constitution of a pixel will next be described with reference to FIGS. 19A and 19B. FIG. 19A is a circuit diagram of the pixel. FIG. 19B shows a part of an example of a sectional constitution of transistors forming the pixel. Incidentally, in FIGS. 19A and 19B, constituent elements similar to those of the pixel 151 of FIGS. 15A and 15B are identified by the same reference symbols, and detailed description thereof will be omitted.

As shown in FIG. 19A, the pixel 151B includes a PD 152, a transfer transistor 153, an FD 154, an amplifying transistor 155, a selecting transistor 156A, and a reset transistor 157. In addition, the pixel 151B is connected with a vertical signal line 158, and is connected with horizontal signal lines 159TRF, 159SEL, and 159RST.

The amplifying transistor 155 in the pixel 151B is formed with the well 164-2 and the N-type region 163-3 (source) of the amplifying transistor 155 electrically connected to each other by wiring 166, and thus has the constitution of the transistor 142 described with reference to FIGS. 12A to 12C. In addition, the selecting transistor 156A in the pixel 151B is formed with the well 164-3 and the gate electrode 165-3 of the selecting transistor 156A electrically connected to each other by wiring 167, and thus has the constitution of the transistor 142A described with reference to FIGS. 16A to 16C.

In the thus formed pixel 151B, as in the pixel 151, conversion efficiency can be greatly improved, and better characteristics can be obtained.

In addition, in relation to the selecting transistor 156A, it is becoming difficult to secure an area for the amplifying transistor 155 as the pixel 151 is miniaturized, and accordingly the L-length of the selecting transistor 156 is desired to be reduced to secure an area for the amplifying transistor 155. In order to deal with this, in the pixel 151B, the gate and the well of the selecting transistor 156A are coupled with each other. Thereby, when the selecting transistor 156A is on, for example, a positive potential is simultaneously applied to the well, so that the threshold value of the selecting transistor 156A can be lowered. In addition, when the selecting transistor 156A is off, for example, a negative potential is simultaneously applied to the well, so that the threshold value of the selecting transistor 156A can be raised. Because the selecting transistor 156A operates in such manners, an operation margin at a time of selection or non-selection can be achieved with the transistor of a short gate length (L-length). That is, shortening the L-length of the selecting transistor 156 in the pixel 151 allows the L-length of the amplifying transistor 155 to be increased. Thus, noise characteristics can be improved.

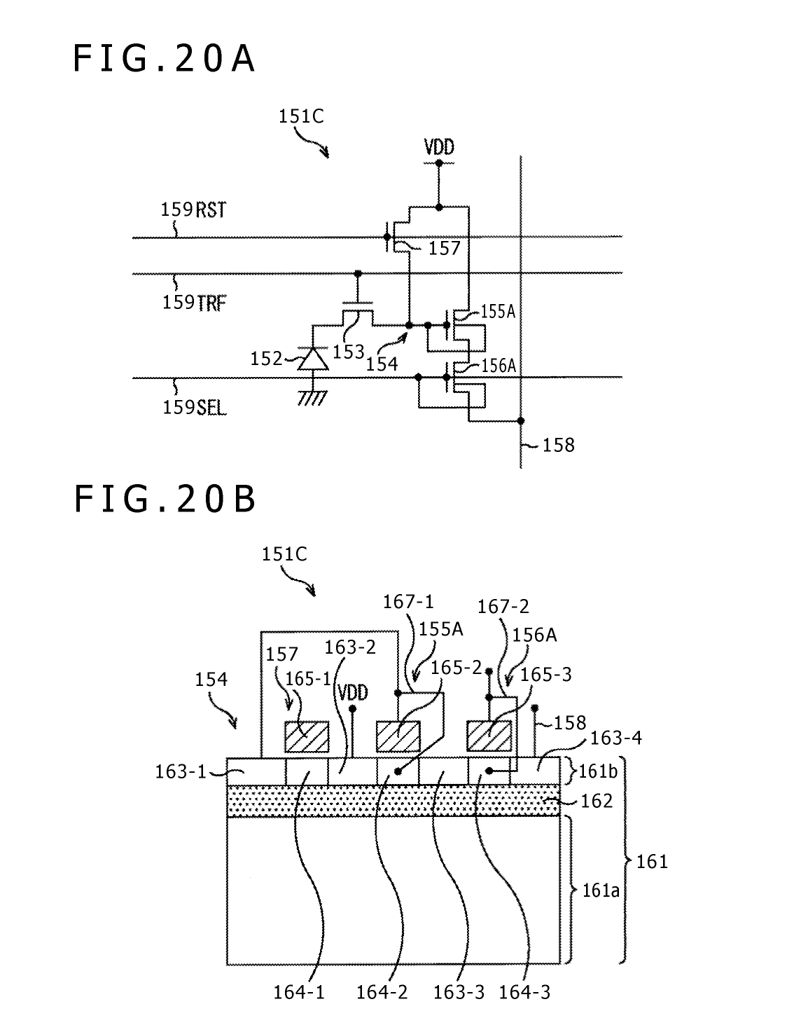

A fourth example of constitution of a pixel will next be described with reference to FIGS. 20A and 20B. FIG. 20A is a circuit diagram of the pixel. FIG. 20B shows a part of an example of a sectional constitution of transistors forming the pixel. Incidentally, in FIGS. 20A and 20B, constituent elements similar to those of the pixel 151 of FIGS. 15A and 15B are identified by the same reference symbols, and detailed description thereof will be omitted.

As shown in FIG. 20A, the pixel 151C includes a PD 152, a transfer transistor 153, an FD 154, an amplifying transistor 155A, a selecting transistor 156A, and a reset transistor 157. In addition, the pixel 151C is connected with a vertical signal line 158, and is connected with horizontal signal lines 159TRF, 159SEL, and 159RST.

The amplifying transistor 155A in the pixel 151C is formed with the well 164-2 and the gate electrode 165-2 of the amplifying transistor 155A electrically connected to each other by wiring 167-1. In addition, the selecting transistor 156A is formed with the well 164-3 and the gate electrode 165-3 of the selecting transistor 156A electrically connected to each other by wiring 167-2. That is, the amplifying transistor 155A and the selecting transistor 156A in the pixel 151C have the constitution of the transistor 142A described with reference to FIGS. 16A to 16C.

In the thus formed pixel 151C, as in the pixel 151, conversion efficiency can be greatly improved, and better characteristics can be obtained. In addition, in the pixel 151C, as in the pixel 151B of FIGS. 19A and 19B, an operation margin at a time of selection or non-selection can be achieved with a transistor of a short L-length, and the L-length of the amplifying transistor 155A can be increased.

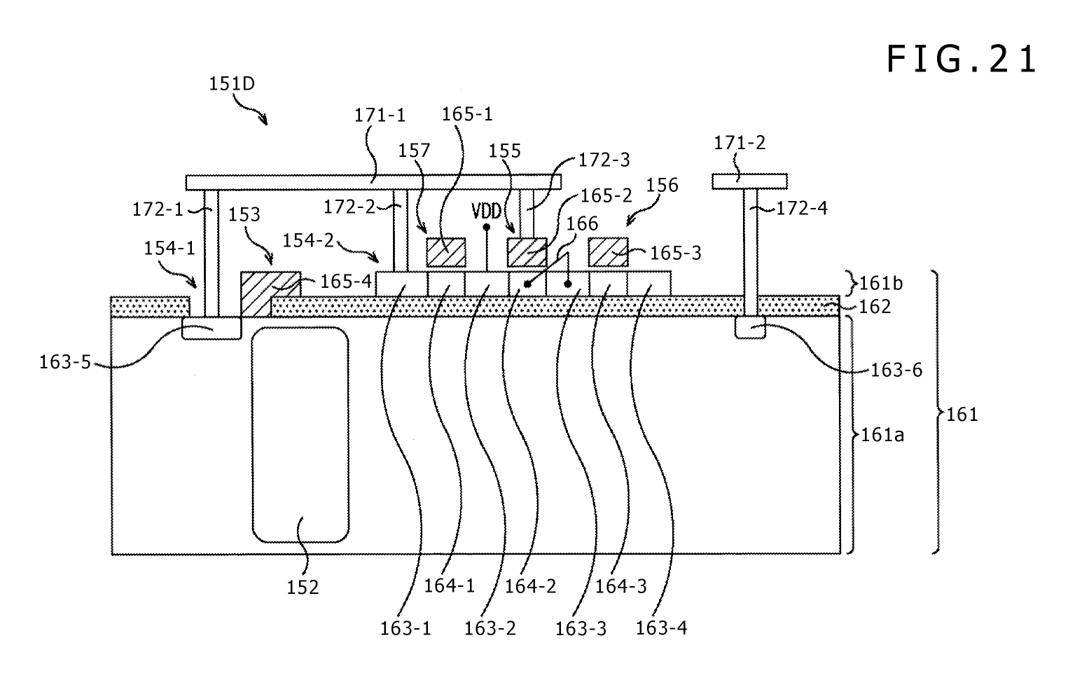

A fifth example of constitution of a pixel will next be described with reference to FIG. 21. FIG. 21 shows a part of an example of a sectional constitution of transistors forming the pixel. In FIG. 21, constituent elements similar to those of the pixel 151 of FIGS. 15A and 15B are identified by the same reference symbols, and detailed description thereof will be omitted.

As shown in FIG. 21, the pixel 151D is formed in an SOI substrate 161.

In the pixel 151D, as in the pixel 151 of FIGS. 15A and 15B, N-type regions 163-1 to 163-4 and wells 164-1 to 164-3 are formed in the surface silicon layer 161b of the SOI substrate 161, and gate electrodes 165-1 to 165-3 are formed above the surface of the SOI substrate 161.

In addition, a PN junction constituting a PD 152 is formed within the silicon substrate layer 161a of the SOI substrate 161. An N-type region 163-5 is formed at a position separated from the PD 152 by a certain interval in such a manner as to be in contact with the surface of the silicon substrate layer 161a. An opening is made in a silicon oxide film 162 in the vicinity of the position where the N-type region 163-5 is formed. A gate electrode 165-4 forming a transfer transistor 153 is formed in the opening part in such a manner as to be in contact with the silicon substrate layer 161a.

An FD 154 in the pixel 151D includes an FD 154-1 formed by the N-type region 163-5 and an FD 154-2 formed by the N-type region 163-1. The N-type region 163-5 and wiring 171-1 are connected to each other via a through electrode 172-1. The N-type region 163-1 and the wiring 171-1 are connected to each other via a through electrode 172-2. In addition, the wiring 171-1 is connected to the gate electrode 165-2 forming an amplifying transistor 155 via a through electrode 172-3.

In addition, in the pixel 151D, an N-type region 163-6 serving as a well contact is formed in such a manner as to be in contact with the surface of the silicon substrate layer 161a of the SOI substrate 161. The N-type region 163-6 is connected to wiring 171-2 via a through electrode 172-4 formed so as to penetrate the silicon oxide film 162. The potential of the silicon substrate layer 161a is supplied from the wiring 171-2 via the through electrode 172-4.

In the pixel 151D, the N-type region 163-3 (source) and the well 164-2 of the amplifying transistor 155 are electrically connected to each other by wiring 166. That is, the amplifying transistor 155 has the constitution of the transistor 142 described with reference to FIGS. 12A to 12C.

Also in the thus formed pixel 151D, conversion efficiency can be greatly improved, and better characteristics can be obtained.

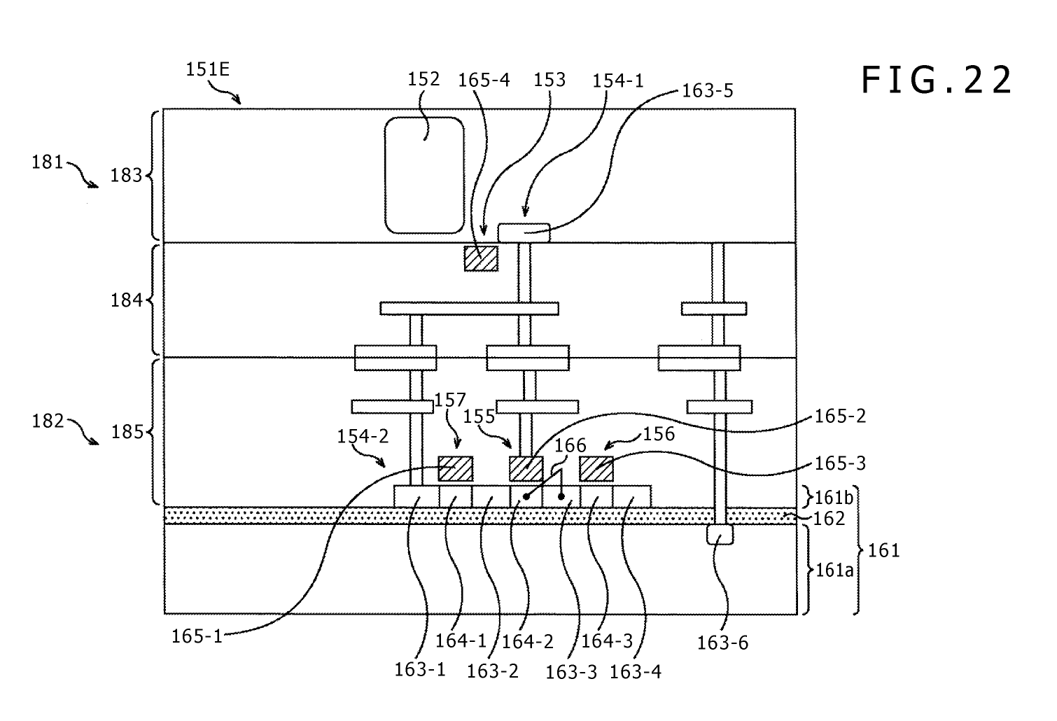

A sixth example of constitution of a pixel will next be described with reference to FIG. 22. FIG. 22 shows a part of an example of a sectional constitution of transistors forming the pixel. In FIG. 22, constituent elements similar to those of the pixel 151 of FIGS. 15A and 15B are identified by the same reference symbols, and detailed description thereof will be omitted.

As shown in FIG. 22, the pixel 151E is formed by bonding a first substrate 181 having a PD 152 and a transfer transistor 153 formed therein to a second substrate 182 having an amplifying transistor 155, a selecting transistor 156, and a reset transistor 157 formed therein.

The first substrate 181 is formed by laminating a wiring layer 184 to a silicon substrate 183.

A PN junction constituting the PD 152 is formed within the silicon substrate 183. An N-type region 163-5 forming an FD 154-1 is formed at a position separated from the PD 152 by a certain interval in such a manner as to be in contact with the surface of the silicon substrate 183 (surface on a lower side in FIG. 22). In addition, a gate electrode 165-4 forming the transfer transistor 153 is formed on the surface side of the silicon substrate 183, and is disposed at a position between the PD 152 and the FD 154-1.

The second substrate 182 is formed by laminating a wiring layer 185 to an SOI substrate 161.

As in the pixel 151 of FIGS. 15A and 15B, N-type regions 163-1 to 163-4 and wells 164-1 to 164-3 are formed in the surface silicon layer 161b of the SOI substrate 161, and gate electrodes 165-1 to 165-3 are formed on the surface side of the surface silicon layer 161b. In addition, in the pixel 151E, an N-type region 163-6 serving as a well contact is formed in such a manner as to be in contact with the surface of the silicon substrate layer 161a of the SOI substrate 161.

In addition, wiring and through electrodes are formed in the wiring layer 184 of the first substrate 181 and the wiring layer 185 of the second substrate 182 so that the FDs 154-1 and 154-2 are connected to the gate electrode 165-2 of the amplifying transistor 155 when the first substrate 181 and the second substrate 182 are bonded together. Similarly, wiring and through electrodes are formed in the wiring layer 184 of the first substrate 181 and the wiring layer 185 of the second substrate 182 so that the N-type region 163-6 (well contact) in the silicon substrate layer 161a is connected to the silicon substrate 183.

In the pixel 151E, the N-type region 163-3 (source) and the well 164-2 of the amplifying transistor 155 are electrically connected to each other by wiring 166. That is, the amplifying transistor 155 has the constitution of the transistor 142 described with reference to FIGS. 12A to 12C.

Also in the thus formed pixel 151E, conversion efficiency can be greatly improved, and better characteristics can be obtained.

Incidentally, while FIG. 21 and FIG. 22 show examples of constitution in which the amplifying transistor 155 has the constitution of the transistor 142 described with reference to FIGS. 12A to 12C, the amplifying transistor 155 may have the constitution of the transistor 142A described with reference to FIGS. 16A to 16C, for example. In addition, as in the pixel 151B of FIGS. 19A and 19B, the amplifying transistor 155 may have the constitution of the transistor 142, and the selecting transistor 156 may have the constitution of the transistor 142A. In addition, as in the pixel 151C of FIGS. 20A and 20B, the amplifying transistor 155 and the selecting transistor 156 may have the constitution of the transistor 142A.

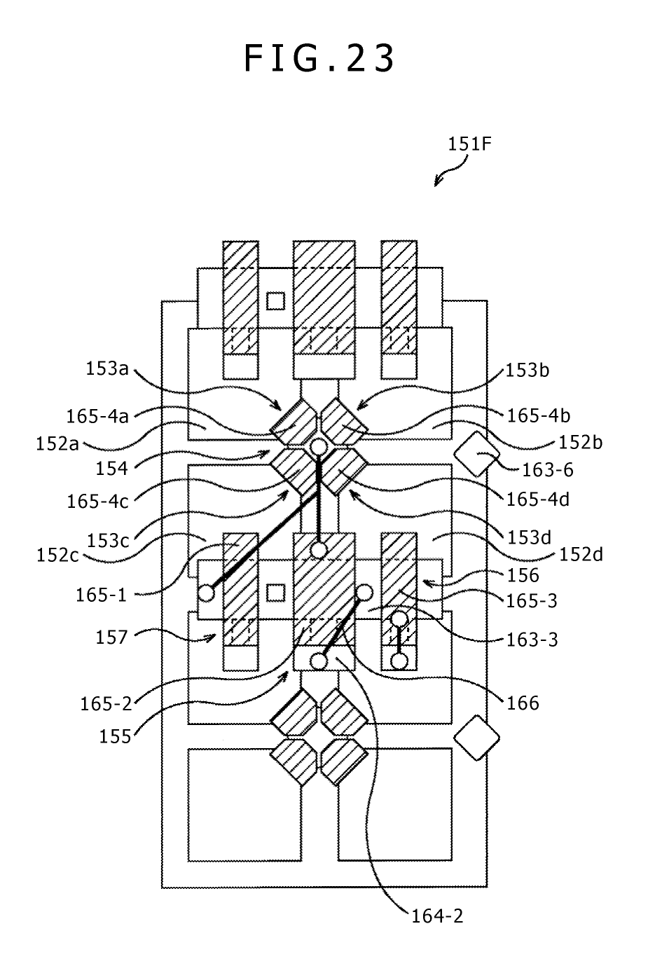

A seventh example of constitution of a pixel will next be described with reference to FIG. 23. FIG. 23 shows an example of a planar constitution of the pixel.

The pixel 151F shown in FIG. 23 has a pixel sharing structure in which four PDs 152a to 152d share an amplifying transistor 155, a selecting transistor 156, and a reset transistor 157.

Specifically, the PD 152a is connected to a FD 154 via a transfer transistor 153a having a gate electrode 165-4a, and the PD 152b is connected to the FD 154 via a transfer transistor 153b having a gate electrode 165-4b. In addition, the PD 152c is connected to the FD 154 via a transfer transistor 153c having a gate electrode 165-4c, and the PD 152d is connected to the FD 154 via a transfer transistor 153d having a gate electrode 165-4d. The FD 154 is connected to the gate electrode 165-2 of the amplifying transistor 155 via wiring.

In the pixel 151F, the N-type region 163-3 (source) and the well 164-2 of the amplifying transistor 155 are electrically connected to each other by wiring 166. That is, the amplifying transistor 155 has the constitution of the transistor 142 described with reference to FIGS. 12A to 12C.

Also in the pixel 151F thus having the pixel sharing structure, conversion efficiency can be greatly improved, and better characteristics can be obtained. Further, because the pixel 151F has the pixel sharing structure, the area of the PDs 152 can be increased with reductions in the areas where the transistors are arranged. This can improve sensitivity.

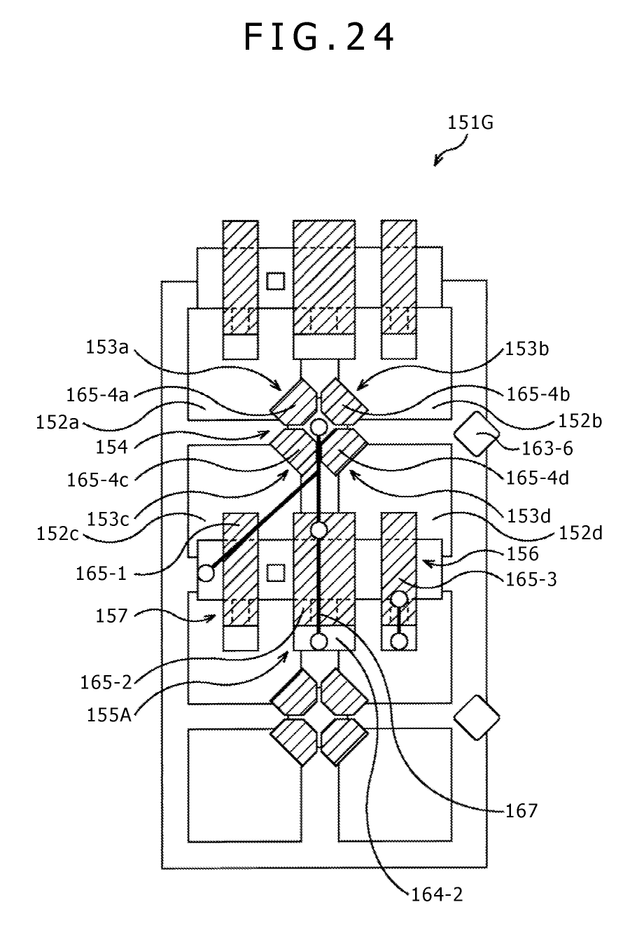

An eighth example of constitution of a pixel will next be described with reference to FIG. 24. FIG. 24 shows an example of a planar constitution of the pixel.

As with the pixel 151F shown in FIG. 23, the pixel 151G shown in FIG. 24 has a pixel sharing structure in which four PDs 152a to 152d share an amplifying transistor 155A, a selecting transistor 156, and a reset transistor 157.

In the pixel 151G, the gate electrode 165-2 and the well 164-2 of the amplifying transistor 155A are electrically connected to each other by wiring 167. That is, the amplifying transistor 155A has the constitution of the transistor 142A described with reference to FIGS. 16A to 16C.

Also in the pixel 151G thus having the pixel sharing structure, conversion efficiency can be greatly improved, and better characteristics can be obtained. Further, because the pixel 151G has the pixel sharing structure, the area of the PDs 152 can be increased with reductions in the areas where the transistors are arranged. This can improve sensitivity.

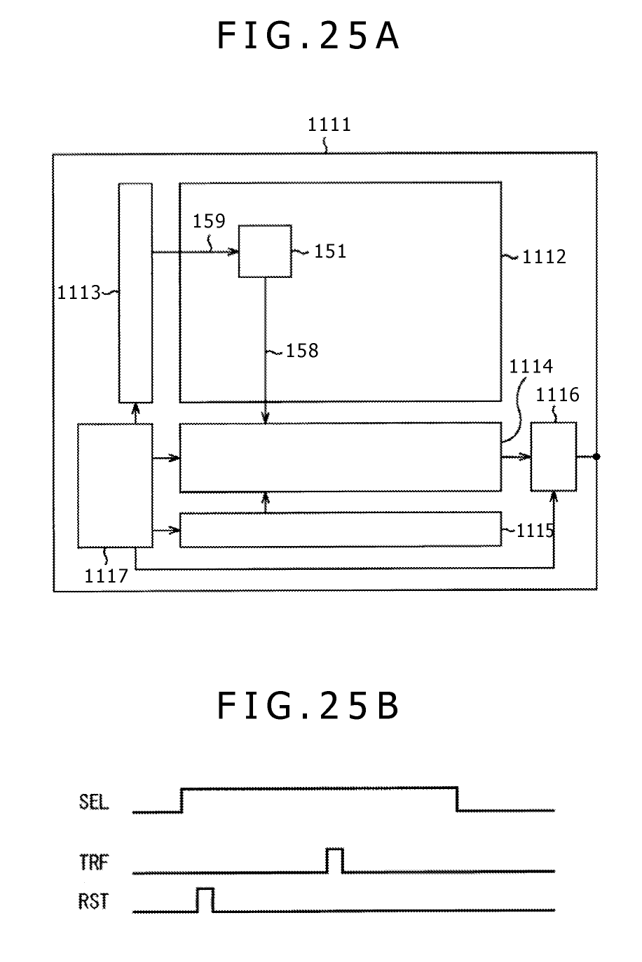

An example of constitution of a solid-state imaging element having pixels 151 in each example of constitution as described above will be described in the following with reference to FIGS. 25A and 25B. FIG. 25A is a block diagram showing an example of constitution of the solid-state imaging element. FIG. 25B shows an example of timing of driving signals for driving a pixel.

As shown in FIG. 25A, the imaging element 1111 includes a pixel array section 1112, a vertical driving section 1113, a column processing section 1114, a horizontal driving section 1115, an output section 1116, and a driving control section 1117.

The pixel array section 1112 has a plurality of pixels 151 arranged in the form of an array. One of the constitution examples described above can be adopted for the pixels 151. In addition, the pixels 151 in the pixel array section 1112 are connected to the vertical driving section 1113 via a plurality of horizontal signal lines 159 corresponding in number to the rows of the pixels 151, and the pixels 151 are connected to the column processing section 1114 via a plurality of vertical signal lines 158 corresponding in number to the columns of the pixels 151.

The vertical driving section 1113 sequentially supplies each row of the plurality of pixels 151 possessed by the pixel array section 1112 with a transfer signal TRF, a selecting signal SEL, and a reset signal RST as driving signals for driving each of the pixels 151 via the horizontal signal lines 159.

Specifically, as shown in FIG. 25B, when timing of reading out pixel signals from pixels 151 of a predetermined row arrives, the vertical driving section 1113 first turns on the selecting signal SEL to select the pixels 151. The amplifying transistors 155 are thereby connected to the vertical signal lines 158 via the selecting transistors 156. The vertical driving section 1113 next turns on the reset signal RST in the form of a pulse to reset the FDs 154. Pixel signals indicating the levels of the FDs 154 in the reset state are thereafter output from the vertical signal lines 158 via the amplifying transistors 155. The vertical driving section 1113 then turns on the transfer signal TRF in the form of a pulse to transfer charges generated in the PDs 152 to the FDs 154. Pixel signals indicating the levels of the FDs 154 in a state of storing the charges are thereafter output from the vertical signal lines 158 via the amplifying transistors 155.

The pixel signals of the reset levels and the pixel signals corresponding to the levels of the charges are thus output from the pixels 151, and read by the column processing section 1114.

The column processing section 1114 extracts the signal levels of the pixel signals by subjecting the pixel signals output from the respective pixels 151 via the vertical signal lines 158 to CDS (Correlated Double Sampling) processing, and thus obtains pixel data corresponding to the amounts of light received by the pixels 151.

The horizontal driving section 1115 sequentially supplies the column processing section 1114 with driving signals for outputting the pixel data obtained from the respective pixels 151 in each column of the plurality of pixels 151 possessed by the pixel array section 1112 in order from the column processing section 1114.

The output section 1116 is supplied with the pixel data from the column processing section 1114 in timing according to the driving signals of the horizontal driving section 1115. The output section 1116, for example, amplifies the pixel data and outputs the amplified pixel data to an image processing circuit in a following stage.

The driving control section 1117 controls the driving of each block within the imaging element 1111. For example, the driving control section 1117 generates a clock signal according to the driving cycles of each block, and supplies the clock signal to each block.

In this case, each of the pixels 151 possessed by the pixel array section 1112 in the imaging element 1111 has one of the constitution examples described above. Thus, conversion efficiency can be greatly improved, and pixel signals with better characteristics can be obtained.

In addition, the imaging element 1111 is applicable to various kinds of electronic devices including, for example, imaging systems such as digital still cameras, digital video cameras, and the like, portable telephones having an imaging function, or other devices having an imaging function.

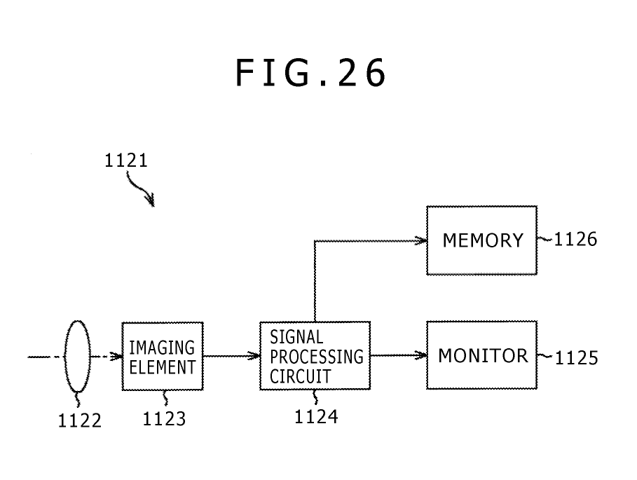

FIG. 26 is a block diagram showing an example of configuration of an imaging device included in an electronic device.

As shown in FIG. 26, the imaging device 1121 includes an optical system 1122, an imaging element 1123, a signal processing circuit 1124, a monitor 1125, and a memory 1126. The imaging device 1121 can take still images and moving images.

The optical system 1122 includes one or a plurality of lenses. The optical system 1122 guides image light (incident light) from a subject to the imaging element 1123 to form an image on the light receiving surface (sensor section) of the imaging element 1123.

The imaging element 1111 including pixels 151 in one of the constitution examples described above is applied as the imaging element 1123. The imaging element 1123 accumulates electrons for a certain period according to the image formed on the light receiving surface via the optical system 1122. A signal corresponding to the electrons accumulated in the imaging element 1123 is then supplied to the signal processing circuit 1124.

The signal processing circuit 1124 subjects the signal charge output from the imaging element 1123 to various kinds of signal processing. An image (image data) obtained by the signal processing of the signal processing circuit 1124 is supplied to the monitor 1125 and displayed on the monitor 1125, or supplied to the memory 1126 and stored (recorded) in the memory 1126.

In the thus formed imaging device 1121, because the imaging element 1111 including pixels 151 in one of the constitution examples described above is applied as the imaging element 1123, conversion efficiency can be greatly improved, and images of better image quality can be obtained.

In addition, the constitution of the imaging element 1111 can be adopted for CMOS type solid-state imaging elements of a back side illumination type, CMOS type solid-state imaging elements of a front side illumination type, and CCD (Charge Coupled Device) type solid-state imaging elements.

The present disclosure contains subject matter related to that disclosed in Japanese Priority Patent Applications JP 2011-273818 and JP 2011-264851 filed in the Japan Patent Office on Dec. 14, 2011 and Dec. 2, 2011, respectively, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state imaging element comprising:
a photoelectric conversion section configured to generate a charge according to received light; and
a plurality of active elements configured to perform predetermined operation on the charge generated in the photoelectric conversion section,
wherein a part of a gate electrode possessed by one of the active elements has a projection part buried in a substrate in which the photoelectric conversion section is formed.

2. The solid-state imaging element according to claim 1,
wherein the one of the active elements is an amplifying transistor for amplifying and outputting the charge generated in the photoelectric conversion section.

3. The solid-state imaging element according to claim 2,
wherein the one of the active elements is a selecting transistor for setting a pixel signal obtained by amplifying the charge generated in the photoelectric conversion section by the amplifying transistor in a state of being able to be output.

4. The solid-state imaging element according to claim 1,
wherein the one of the active elements is a transfer transistor for transferring the charge generated in the photoelectric conversion section to a floating diffusion region.

5. The solid-state imaging element according to claim 4,
wherein the one of the active elements is a reset transistor for resetting a potential of the floating diffusion region.

6. The solid-state imaging element according to claim 1,
wherein a channel region is formed along a bottom surface of the gate electrode and a bottom surface and a side surface of the projection part of the gate electrode.

7. The solid-state imaging element according to claim 1,
wherein the projection part of the gate electrode is formed along a direction of length of the active element.

8. The solid-state imaging element according to claim 7,
wherein the projection part of the gate electrode is formed in substantially a center in a direction of width of the active element.

9. The solid-state imaging element according to claim 7,
wherein the projection part of the gate electrode is formed in vicinities of both ends in a direction of width of the active element.

10. The solid-state imaging element according to claim 1,
wherein the projection part of the gate electrode is formed along a direction of width of the active element.

11. The solid-state imaging element according to claim 10,
wherein the projection part of the gate electrode is formed in substantially a center in a direction of length of the active element.

12. The solid-state imaging element according to claim 10,
wherein the projection part of the gate electrode is formed in vicinities of both ends in a direction of length of the active element.

13. An electronic device including a solid-state imaging element, the solid-state imaging element comprising:
a photoelectric conversion section configured to generate a charge according to received light; and
a plurality of active elements configured to perform predetermined operation on the charge generated in the photoelectric conversion section,
wherein a part of a gate electrode possessed by one of the active elements has a projection part buried in a substrate in which the photoelectric conversion section is formed.

14. An amplifying circuit comprising:
an impurity region of a first type formed in a surface silicon layer of a semiconductor substrate, the semiconductor substrate having an insulating film formed between a silicon substrate layer of the semiconductor substrate and the surface silicon layer, the impurity region of the first type being formed from a surface of the surface silicon layer to the insulating film;
an electrode formed on a surface side of the semiconductor substrate;
an electrically independent impurity region of a second type surrounded by the impurity region of the first type in two positions and the insulating film; and
a connecting section configured to connect the impurity region of the second type to one of the impurity region of the first type and the electrode.

15. A method of manufacturing an amplifying circuit, the method comprising:
forming an impurity region of a first type in a surface silicon layer of a semiconductor substrate, the semiconductor substrate having an insulating film formed between a silicon substrate layer of the semiconductor substrate and the surface silicon layer, from a surface of the surface silicon layer to the insulating film;
forming an electrode on a surface side of the semiconductor substrate; and
connecting an electrically independent impurity region of a second type surrounded by the impurity region of the first type in two positions and the insulating film to one of the impurity region of the first type and the electrode.

16. An imaging element comprising:
a photoelectric conversion section configured to generate a charge according to a light amount of received light; and
an amplifying section configured to amplify the charge generated in the photoelectric conversion section, and output the amplified charge,
wherein the amplifying section includes
an impurity region of a first type formed in a surface silicon layer of a semiconductor substrate, the semiconductor substrate having an insulating film formed between a silicon substrate layer of the semiconductor substrate and the surface silicon layer, the impurity region of the first type being formed from a surface of the surface silicon layer to the insulating film,
an electrode formed on a surface side of the semiconductor substrate,
an electrically independent impurity region of a second type surrounded by the impurity region of the first type in two positions and the insulating film, and
a connecting section configured to connect the impurity region of the second type to one of the impurity region of the first type and the electrode.

17. The imaging element according to claim 16, further comprising
a selecting section configured to select connection of the amplifying section to a signal line,
wherein the selecting section includes
an impurity region of the first type formed in the surface silicon layer of the semiconductor substrate, the semiconductor substrate having the insulating film formed between the silicon substrate layer and the surface silicon layer, the impurity region of the first type being formed from the surface of the surface silicon layer to the insulating film,
an electrode formed on the surface side of the semiconductor substrate,
an electrically independent impurity region of the second type surrounded by the impurity region of the first type in two positions and the insulating film, and
a connecting section configured to connect the impurity region of the second type to the electrode.

18. The imaging element according to claim 16,
wherein a connecting section connected with a through electrode penetrating the insulating film is formed in the silicon substrate layer in which the photoelectric conversion section is formed.

19. The imaging element according to claim 16,
wherein the photoelectric conversion section and the amplifying section are formed in different substrates, and the substrates are bonded to each other to form the imaging element.

20. The imaging element according to claim 16,
wherein the imaging element has a sharing structure such that the amplifying section is shared by a plurality of photoelectric conversion sections.

21. An electronic device including an imaging element, the imaging element comprising:
a photoelectric conversion section configured to generate a charge according to a light amount of received light; and
an amplifying section configured to amplify the charge generated in the photoelectric conversion section, and output the amplified charge,
wherein the amplifying section includes
an impurity region of a first type formed in a surface silicon layer of a semiconductor substrate, the semiconductor substrate having an insulating film formed between a silicon substrate layer of the semiconductor substrate and the surface silicon layer, the impurity region of the first type being formed from a surface of the surface silicon layer to the insulating film,
an electrode formed on a surface side of the semiconductor substrate,
an electrically independent impurity region of a second type surrounded by the impurity region of the first type in two positions and the insulating film, and
a connecting section configured to connect the impurity region of the second type to one of the impurity region of the first type and the electrode.
